(19) United States
(12) Patent Application Publication
(10) Pub. No.: US 2025/0331366 A1
(43) Pub. Date: Oct. 23, 2025

(54) DISPLAY PANEL

(71) Applicant: Samsung Display Co., Ltd., Yongin-si (KR)

(72) Inventors: YEONGWOO KWON, Yongin-si (KR); DOKEUN SONG, Yongin-si (KR); HYOUNG SIK KIM, Yongin-si (KR); Taesang PARK, Yongin-si (KR); JONGHOON CHOI, Yongin-si (KR)

(21) Appl. No.: 19/017,262

(22) Filed: Jan. 10, 2025

(30) Foreign Application Priority Data
Apr. 19, 2024 (KR) 10-2024-0052426

(51) Int. Cl. H10K 59/122; H10K 59/131; H10K 59/88

(52) U.S. Cl. CPC H10K 59/122; H10K 59/131; H10K 59/88

(57) ABSTRACT

A display panel includes a pixel defining layer having a light emitting opening in a display area, a barrier wall that is on the pixel defining layer and that has a barrier wall opening that is in the display area and that overlaps the light emitting opening, an anode in the display area and at least partially exposed by the light emitting opening, a cathode that is in the display area and that makes contact with the barrier wall in the barrier wall opening, an emission pattern located between the anode and the cathode, and an anchor that is in a non-display area that surrounds at least a portion of the display area.

### CROSS-REFERENCE TO RELATED APPLICATIONS

The present application claims priority to and the benefit of Korean Patent Application No. 10-2024-0052426, filed on Apr. 19, 2024, in the Korean Intellectual Property Office, the entire disclosure of which is incorporated by reference herein.

### BACKGROUND

Embodiments of the present disclosure described herein relate to a display panel, and more particularly, relate to a display panel with improved display quality.

A display device, such as a television, a monitor, a smart phone, a tablet computer, and/or the like, which provides an image to a user includes a display panel that displays an image. Various display panels, such as a liquid crystal display panel, an organic light emitting display panel, an electro wetting display panel, an electrophoretic display panel, and/or the like, are being developed.

The organic light emitting display panel may include anodes, cathodes, and emission patterns. The emission patterns may be divided from one another for respective emissive areas, and the cathodes may provide a common voltage for the respective emissive areas.

### SUMMARY

Embodiments of the present disclosure provide a display panel with improved process reliability in which light emitting elements are formed without using a metal mask.

According to one or more embodiments, a display panel includes a pixel defining layer having a light emitting opening in a display area, a barrier wall that is on the pixel defining layer and that has a barrier wall opening that is in the display area and that overlaps the light emitting opening, an anode in the display area and at least partially exposed by the light emitting opening, a cathode that is in the display area and that makes contact with the barrier wall in the barrier wall opening, an emission pattern located between the anode and the cathode, and an anchor that is in a non-display area that surrounds at least a portion of the display area.

The barrier wall may include a first barrier wall layer on the pixel defining layer and a second barrier wall layer on the first barrier wall layer. The barrier wall opening may include a first opening area defined by an inner surface of the first barrier wall layer and a second opening area that is defined by an inner surface of the second barrier wall layer and that has a smaller width than the first opening area.

The display panel may further include a first dummy pattern on the barrier wall, the first dummy pattern includes a first-first layer dummy pattern including a same material as the emission pattern and a second-first layer dummy pattern including a same material as the cathode and a lower inorganic encapsulation pattern that at least partially overlaps the barrier wall opening and covers the cathode.

The non-display area may include a first non-display area and a second non-display area spaced from the display area with the first non-display area therebetween. The barrier wall may include an inner portion in the display area, the inner portion has the barrier wall opening and an outer portion in the second non-display area, the outer portion has an outer opening.

The display panel may further include a driving voltage line that is at least partially located in the second non-display area and that receives a bias voltage, and the outer portion of the barrier wall may be connected to the driving voltage line in the second non-display area.

The barrier wall may further include an anchor portion in the first non-display area, the anchor portion has an anchor opening, and the anchor may be provided by the anchor portion of the barrier wall.

The anchor opening may include a third opening area defined by an inner surface of the first barrier wall layer and a fourth opening area that is defined by an inner surface of the second barrier wall layer and that has a smaller width than the third opening area.

The display panel may further include a second dummy pattern in the anchor opening, the second dummy pattern includes a first-second layer dummy pattern including a same material as the emission pattern and a second-second layer dummy pattern including a same material as the cathode and a third dummy pattern on the anchor portion of the anchor, the third dummy pattern includes a first-third layer dummy pattern including a same material as the emission pattern and a second-third layer dummy pattern including a same material as the cathode.

The display panel may further include an outer lower inorganic encapsulation pattern that is in the non-display area and that covers the second dummy pattern and the third dummy pattern.

The anchor opening may include a plurality of anchor openings, and the plurality of anchor openings may be arranged in a matrix form when viewed from above a plane.

The anchor opening may have one of a line shape, a mesh shape, or a zigzag shape when viewed from above a plane.

The display panel may further include anchor patterns in the first non-display area and spaced from the barrier wall. Each of the anchor patterns may include a first anchor layer on the pixel defining layer, the first anchor layer includes a same material as the first barrier wall layer and a second anchor layer on the first anchor layer, the second anchor layer includes a same material as the second barrier wall layer. An outer surface of the second anchor layer may protrude further than an outer surface of the first anchor layer, and the anchor may be provided by the anchor patterns.

The display panel may further include a second dummy pattern on an upper surface of the pixel defining layer exposed from the anchor patterns, the second dummy pattern includes a first-second layer dummy pattern including a same material as the emission pattern and a second-second layer dummy pattern including a same material as the cathode, third dummy patterns that is on the anchor patterns, respectively, and that includes a first-third layer dummy pattern including the same material as the emission pattern and a second-third layer dummy pattern including the same material as the cathode, and an outer lower inorganic encapsulation pattern that is in the first non-display area and that covers the second dummy pattern and the third dummy patterns.

The anchor patterns may be arranged in a matrix form when viewed from above a plane, or each of the anchor patterns may have one of a line shape, a mesh shape, or a zigzag shape when viewed from above the plane.

The display panel may further include an anchor layer that is in the first non-display area and spaced from the barrier wall and that has an inverted tapered shape on a section, and the anchor may be provided by the anchor layer.

The display panel may further include an insulating layer under the pixel defining layer, the insulating layer has a recessed portion in the first non-display area. The pixel defining layer may have an anchor opening that overlaps the recessed portion and forms an integrated space with the recessed portion, and the recessed portion and the anchor opening may provide a trench. The anchor may be provided by the insulating layer located in the first non-display area and the pixel defining layer in the first non-display area.

A maximum width of the recessed portion on a section may be greater than a width of the anchor opening on the section, and a portion of the pixel defining layer that protrudes toward the inside of the trench from the insulating layer may define a tip portion.

The display area may include a first straight side and a second straight side that are spaced from each other in a first direction and that extend in a second direction crossing the first direction, a third straight side and a fourth straight side that are spaced from each other in the second direction and that extend in the first direction, and first to fourth curved sides between the first and third straight sides, between the second and third straight sides, between the third and fourth straight sides, and between the first and fourth straight sides. A first non-display area may include first-first and second-first straight areas that extend along the first and second straight sides, respectively, third-first and fourth-first straight areas that extend along the third and fourth straight sides, respectively, and first-first to fourth-first curved areas that extend along the first-first to fourth-first curved sides, respectively. The anchor may be in at least a part of the first-first to fourth-first curved areas.

According to an embodiment, a display panel includes a base layer, a pixel defining layer that is on the base layer and that has a light emitting opening in a display area, a barrier wall that is on the pixel defining layer and that has a barrier wall opening that is in the display area and that overlaps the light emitting opening, an anode in the display area and at least partially exposed by the light emitting opening, a cathode that is in the display area and that makes contact with the barrier wall in the barrier wall opening, an emission pattern between the anode and the cathode, an anchor that is in a first non-display area and that surrounds at least a portion of the display area, a first dummy pattern on the barrier wall in the display area, a second dummy pattern on an upper surface of the pixel defining layer exposed from the anchor in the first non-display area, a third dummy pattern on the anchor in the first non-display area, and an outer lower inorganic encapsulation pattern that covers the anchor, the second dummy pattern, and the third dummy pattern. The barrier wall includes an inner portion in the display area and an outer portion in a second non-display area spaced from the display area with the first non-display area therebetween.

The anchor may have one of an undercut shape, an inverted tapered shape, and a trench shape.

An electronic device includes: a processor configured to provide input image data to a display panel, the display panel including: a base layer; a pixel defining layer on the base layer, the pixel defining layer having a light emitting opening in a display area; a barrier wall on the pixel defining layer, the barrier wall having a barrier wall opening in the display area and overlapping the light emitting opening; an anode in the display area and at least partially exposed by the light emitting opening; a cathode in the display area and contacting with the barrier wall in the barrier wall opening; an emission pattern located between the anode and the cathode; an anchor in a non-display area surrounding at least a portion of the display area; and a first dummy pattern on the barrier wall. The the electronic device is a personal computer, a notebook computer, a personal digital terminal, a car navigation unit, a game machine, a smart phone, a tablet computer, or a camera.

### BRIEF DESCRIPTION OF THE DRAWINGS

The above and other aspects and features of the present disclosure will become apparent by describing in detail embodiments thereof with reference to the accompanying drawings.

FIG. 1A is a perspective view of a display device according to one or more embodiments of the present disclosure.

FIG. 1B is an exploded perspective view of the display device according to one or more embodiments of the present disclosure.

FIG. 2 is a sectional view of a display panel according to one or more embodiments of the present disclosure.

FIG. 3 is a plan view of the display panel according to one or more embodiments of the present disclosure.

FIG. 4 is an enlarged plan view of a portion of a display area of the display panel according to one or more embodiments of the present disclosure.

FIG. 5 is an enlarged sectional view of a portion of the display area of the display panel according to one or more embodiments of the present disclosure.

FIG. 6 is a sectional view of the display panel taken along the line I-I′ of FIG. 4 according to one or more embodiments of the present disclosure.

FIG. 7 is an enlarged plan view of a partial region of the display panel according to one or more embodiments of the present disclosure.

FIG. 8 is an enlarged sectional view of a portion of the display area and a portion of a non-display area of the display panel according to one or more embodiments of the present disclosure.

FIG. 9 is an enlarged sectional view of a portion of a first non-display area of the display panel according to one or more embodiments of the present disclosure.

FIG. 10 is an enlarged plan view of a partial region of the display panel according to one or more embodiments of the present disclosure.

FIG. 11 is an enlarged sectional view of a portion of the first non-display area of the display panel according to one or more embodiments of the present disclosure.

FIGS. 12A and 12B are enlarged plan views of a partial region of the display panel according to one or more embodiments of the present disclosure.

FIG. 13 is an enlarged plan view of a partial region of the display panel according to one or more embodiments of the present disclosure.

FIGS. 14A and 14B are enlarged plan views of a partial region of the display panel according to one or more embodiments of the present disclosure.

FIG. 15 is a schematic plan view of the display panel according to one or more embodiments of the present disclosure.

FIGS. 16 and 17 are enlarged sectional views of a portion of the first non-display area of the display panel according to one or more embodiments of the present disclosure.

FIG. 18 is an enlarged sectional view of a portion of the first non-display area of the display panel according to one or more embodiments of the present disclosure.

### DETAILED DESCRIPTION

In this specification, when it is mentioned that a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and/or the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application. For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described with reference to the accompanying drawings.

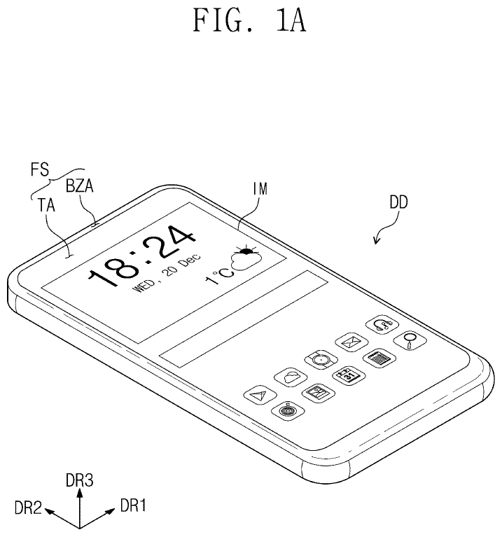

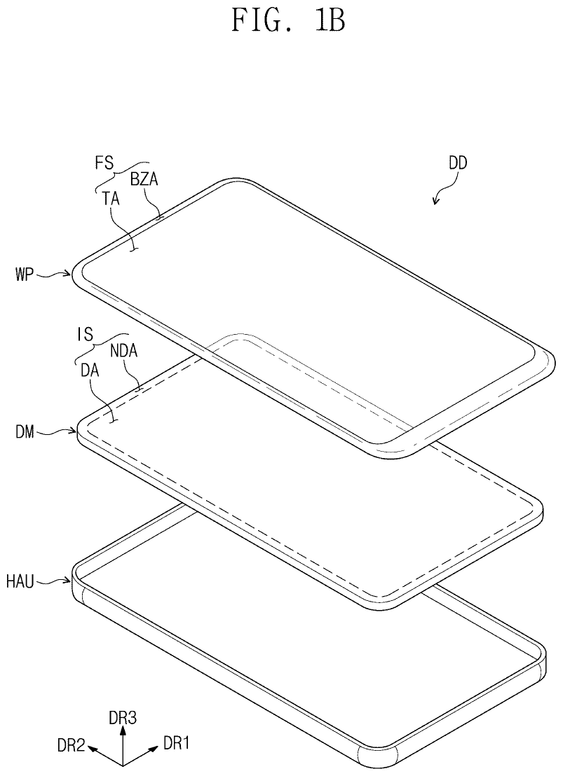

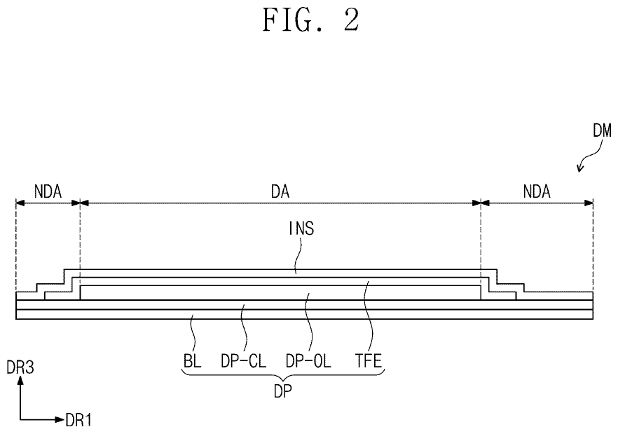

FIG. 1A is a perspective view of a display device according to one or more embodiments of the present disclosure. FIG. 1B is an exploded perspective view of the display device according to one or more embodiments of the present disclosure. FIG. 2 is a sectional view of a display panel according to one or more embodiments of the present disclosure.

In one or more embodiments, the display device DD may be a large electronic device such as a television, a monitor, and/or a billboard. Alternatively, the display device DD may be a small and/or a medium-sized electronic device such as a personal computer, a notebook computer, a personal digital terminal, a car navigation unit, a game machine, a smart phone, a tablet computer, and/or a camera. However, these devices are merely illustrative, and the display device DD may be employed as other display devices without departing from the spirit and scope of the present disclosure. In this embodiment, the display device DD is illustrated as a smart phone.

Referring to FIGS. 1A, 1B, and 2, the display device DD may display an image IM in a third direction DR3 on a display surface FS parallel to a first direction DR1 and a second direction DR2. The image IM may include a still image as well as a dynamic image (e.g., a moving image). In FIG. 1A, a clock window and icons are illustrated as examples of the image IM. The display surface FS on which the image IM is displayed may correspond to the front surface of the display device DD.

In this embodiment, front surfaces (or, upper surfaces) and rear surfaces (or, lower surfaces) of members are defined based on the direction in which the image IM is displayed. The front surfaces and the rear surfaces may face away from each other in the third direction DR3, and the normal directions of the front surfaces and the rear surfaces may be parallel to the third direction DR3. In one or more embodiments, the directions indicated by the first to third directions DR1, DR2, and DR3 may be relative concepts and may be changed to other directions. As used herein, the expression “when viewed from above a plane” (e.g., in a plan view) may mean that it is viewed in the third direction DR3.

As illustrated in FIG. 1B, the display device DD according to this embodiment may include a window WP, a display module DM, and a housing HAU. The window WP and the housing HAU may be coupled with each other to form the exterior of the display device DD.

The window WP may include an optically clear insulating material. For example, the window WP may include glass and/or plastic. The front surface of the window WP may define the display surface FS of the display device DD. The display surface FS may include a transmissive area TA and a bezel area BZA disposed around an edge or a periphery of the transmissive area TA. The transmissive area TA may be an optically clear area. For example, the transmissive area TA may be an area having a visible light transmittance of about 90% or more.

The bezel area BZA may be an area having a lower light transmittance than the transmissive area TA. The bezel area BZA may define the shape of the transmissive area TA. The bezel area BZA may be adjacent to the transmissive area TA and may surround the transmissive area TA. This is illustrative, and in the window WP according to one or more embodiments of the present disclosure, the bezel area BZA may be omitted. The window WP may include at least one of an anti-fingerprint layer, a hard coating layer, and/or an anti-reflective layer and is not limited to any one embodiment.

The display module DM may be disposed under the window WP. The display module DM may be a component that substantially generates the image IM. The image IM generated by the display module DM may be displayed on a display surface IS of the display module DM and may be visually recognized by a user from the outside through the transmissive area TA.

The display module DM includes a display area DA and a non-display area NDA disposed around an edge or a periphery of the display area DA. The display area DA may be an area activated depending on an electrical signal. The non-display area NDA is adjacent to the display area DA. The non-display area NDA may surround the display area DA. The non-display area NDA may be an area covered by the bezel area BZA and may not be visible from the outside.

As illustrated in FIG. 2, the display module DM may include the display panel DP and an input sensor INS. In one or more embodiments, the display device DD (refer to FIG. 1A) according to one or more embodiments of the present disclosure may further include a protective member disposed on the lower surface of the display panel DP and/or an anti-reflective member and/or a window member disposed on the upper surface of the input sensor INS.

The display panel DP may be an emissive display panel. However, this is illustrative, and the present disclosure is not particularly limited thereto. For example, the display panel DP may be an organic light emitting display panel or an inorganic light emitting display panel. An emissive layer in the organic light emitting display panel may include an organic luminescent material. An emissive layer in the inorganic light emitting display panel may include quantum dots, quantum rods, and/or micro LEDs. Hereinafter, it will be exemplified that the display panel DP is an organic light emitting display panel.

The display panel DP may include a base layer BL, and a circuit element layer DP-CL, a display element layer DP-OL, and a thin film encapsulation layer TFE that are disposed on the base layer BL. The input sensor INS may be directly disposed on the thin film encapsulation layer TFE. As used herein, the expression “component A is directly disposed on component B” means that an adhesive layer is not disposed between component A and component B.

The base layer BL may include at least one plastic film. The base layer BL may be a flexible substrate and may include a plastic substrate, a glass substrate, a metal substrate, and/or an organic and/or inorganic composite substrate. The display area DA and the non-display area NDA described with reference to FIG. 1B may be identically defined in the base layer BL.

The circuit element layer DP-CL may include at least one insulating layer and a circuit element. The insulating layer may include at least one inorganic layer and at least one organic layer. The circuit element includes signal lines and a pixel drive circuit.

The display element layer DP-OL may include barrier walls and light emitting elements. Each of the light emitting elements may include an anode, an intermediate layer, and a cathode.

The thin film encapsulation layer TFE may include a plurality of thin films. Some of the thin films may be disposed to improve optical efficiency, and the other one of the thin films may be disposed to protect organic light emitting diodes.

The input sensor INS obtains coordinate information of an external input. The input sensor INS may have a multi-layer structure. The input sensor INS may include a single conductive layer or multiple conductive layers. In addition, the input sensor INS may include a single insulating layer or multiple insulating layers. The input sensor INS may sense the external input in a capacitance type. However, this is illustrative, and the present disclosure is not limited thereto. For example, in one or more embodiments, the input sensor INS may sense the external input using an electromagnetic induction method and/or a pressure sensing method. In one or more embodiments of the present disclosure, the input sensor INS may be omitted.

As illustrated in FIG. 1B, the housing HAU may be coupled with the window WP. The housing HAU may be coupled with the window WP to provide an inner space. The display module DM may be accommodated in the inner space.

The housing HAU may include a material having a relatively high rigidity. For example, the housing HAU may include glass, plastic, and/or metal, and/or may include a plurality of frames and/or plates formed of a combination of the aforementioned materials. The housing HAU may stably protect components of the display device DD accommodated in the inner space from external impact.

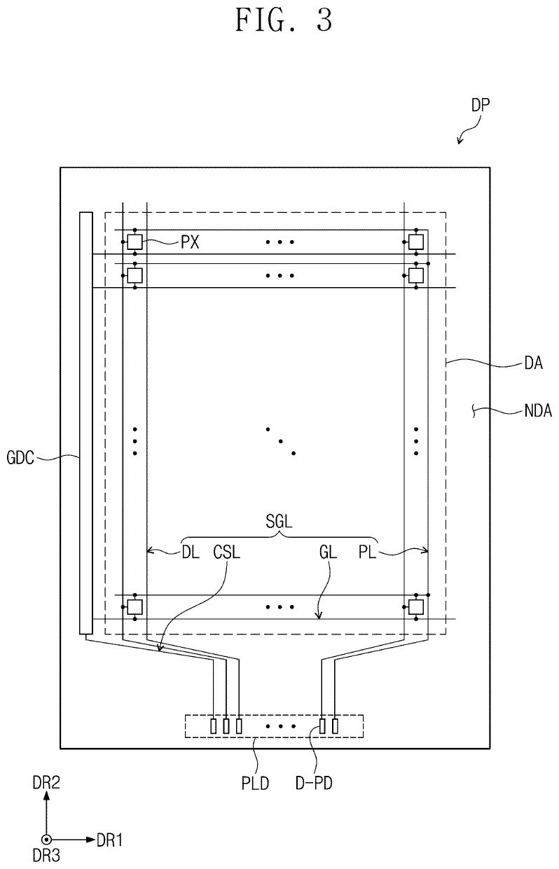

FIG. 3 is a plan view of the display panel according to one or more embodiments of the present disclosure.

Referring to FIG. 3, the display area DA and the non-display area NDA around the display area DA may be defined in the display panel DP. The display panel DP may include pixels PX and signal lines SGL electrically connected to the pixels PX. The display panel DP may include a driving circuit GDC and a pad part PLD. The display area DA and the non-display area NDA may be distinguished from each other depending on whether the pixels PX are disposed. The pixels PX may be disposed in the display area DA. The driving circuit GDC and the pad part PLD may be disposed in the non-display area NDA.

The pixels PX may be arranged along the first direction DR1 and the second direction DR2. The pixels PX may include a plurality of pixel rows that extends in the first direction DR1 and that are arranged along the second direction DR2 and a plurality of pixel columns that extends in the second direction DR2 and that are arranged along the first direction DR1.

The signal lines SGL may include gate lines GL, data lines DL, a power line PL, and a control signal line CSL. Each of the gate lines GL may be connected to a corresponding pixel from among the pixels PX, and each of the data lines DL may be connected to a corresponding pixel from among the pixels PX. The power line PL may be electrically connected to the pixels PX. The control signal line CSL may be connected to the driving circuit GDC and may provide control signals to the driving circuit GDC.

The driving circuit GDC may include a gate driving circuit. The gate driving circuit may generate gate signals and may sequentially output the generated gate signals to the gate lines GL. The gate driving circuit may additionally output other control signals to the pixel driving circuit.

The pad part PLD may be a part to which a flexible circuit board is connected. The pad part PLD may include pixel pads D-PD, and the pixel pads D-PD may be pads for connecting the flexible circuit board to the display panel DP. Each of the pixel pads D-PD may be connected with a corresponding signal line from among the signal lines SGL. The pixel pads D-PD may be connected to the corresponding pixels PX through the signal lines SGL. Furthermore, one pixel pad from among the pixel pads D-PD may be connected to the driving circuit GDC.

In addition, the pad part PLD may further include input pads. The input pads may be pads for connecting a flexible circuit board to the input sensor INS (refer to FIG. 2). However, without being limited thereto, the input pads may be disposed on the input sensor INS (refer to FIG. 2) and may be connected with the pixel pads D-PD and a separate circuit board. Alternatively, the input sensor INS (refer to FIG. 2) may be omitted, and the input pads may not be additionally included.

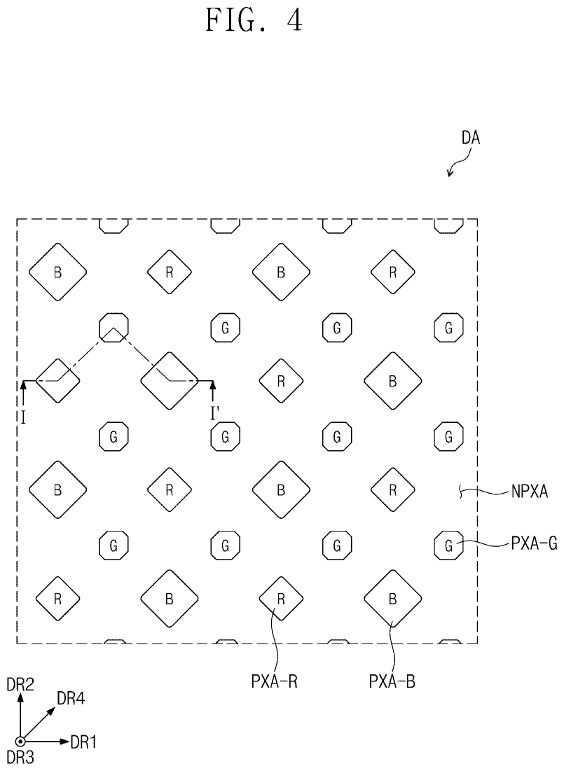

FIG. 4 is an enlarged plan view of a portion of the display area of the display panel according to one or more embodiments of the present disclosure. FIG. 4 is a plan view of the display module DM as viewed from above the display surface IS (refer to FIG. 1B) of the display module DM (refer to FIG. 1B) and illustrates an arrangement of emissive areas PXA-R, PXA-G, and PXA-B.

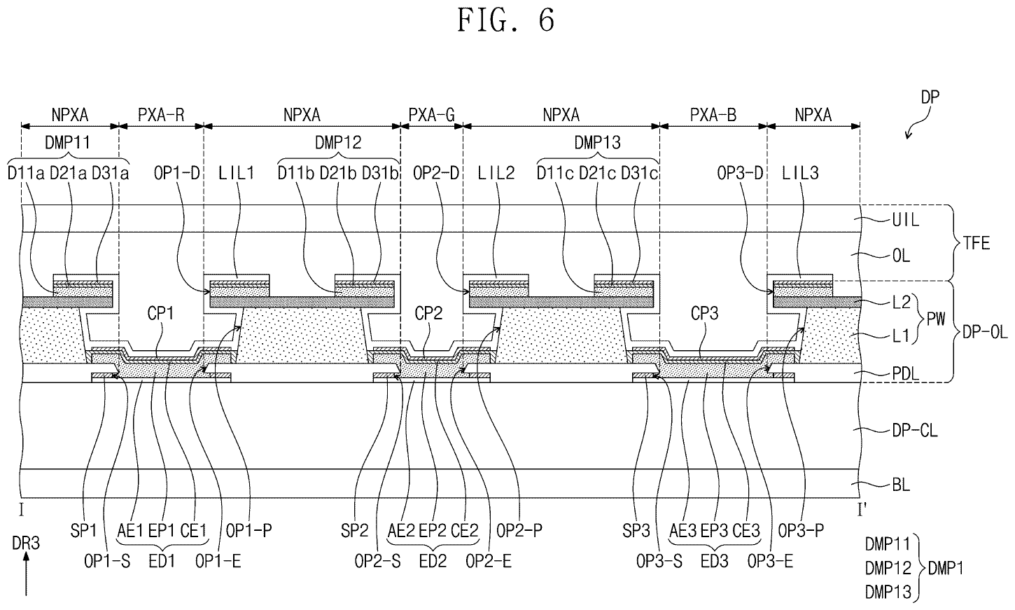

Referring to FIG. 4, the display area DA may include the first to third emissive areas PXA-R, PXA-G, and PXA-B and a peripheral area NPXA around (e.g., surrounding) the first to third emissive areas PXA-R, PXA-G, and PXA-B. The first to third emissive areas PXA-R, PXA-G, and PXA-B may correspond to areas through which light provided from light emitting elements ED1, ED2, and ED3 (refer to FIG. 6) is emitted. The first to third emissive areas PXA-R, PXA-G, and PXA-B may be distinguished from one another depending on the colors of light emitted toward the outside of the display module DM (refer to FIG. 2).

The first to third emissive areas PXA-R, PXA-G, and PXA-B may provide light of a first color, light of a second color, and light of a third color that have different colors, respectively. For example, the light of the first color may be red light, the light of the second color may be green light, and the light of the third color may be blue light. However, examples of the light of the first color, the light of the second color, and the light of the third color are not necessarily limited thereto.

The first to third emissive areas PXA-R, PXA-G, and PXA-B may be defined as areas where the upper surfaces of anodes are exposed by light emitting openings that will be described below. The peripheral area NPXA may set the boundaries between the first to third emissive areas PXA-R, PXA-G, and PXA-B and may prevent color mixing between the first to third emissive areas PXA-R, PXA-G, and PXA-B.

A plurality of first emissive areas PXA-R, a plurality of second emissive areas PXA-G, and a plurality of third emissive areas PXA-B may be provided. The plurality of first emissive areas PXA-R, the plurality of second emissive areas PXA-G, and the plurality of third emissive areas PXA-B may be repeatedly disposed in a certain arrangement in the display area DA. For example, the first and third emissive areas PXA-R and PXA-B may be alternately arranged along the first direction DR1 to form a “first group”. The second emissive areas PXA-G may be arranged along the first direction DR1 to form a “second group”. A plurality of “first groups” and a plurality of “second groups” may be provided. The “first groups” and the “second groups” may be alternately arranged along the second direction DR2.

One second emissive area PXA-G may be spaced (e.g., spaced apart) from one first emissive area PXA-R or one third emissive area PXA-B in a fourth direction DR4. The fourth direction DR4 (e.g., a diagonal direction) may be defined as a direction that crosses the first direction DR1 and the second direction DR2 when viewed from above a plane defined by the first direction DR1 and the second direction DR2.

In FIG. 4, the arrangement of the first to third emissive areas PXA-R, PXA-G, and PXA-B is illustrated as an example, and without being limited thereto, the first to third emissive areas PXA-R, PXA-G, and PXA-B may be arranged in various forms. In one or more embodiments, the first to third emissive areas PXA-R, PXA-G, and PXA-B may have a PENTILE® arrangement as illustrated in FIG. 4. Alternatively, the first to third emissive areas PXA-R, PXA-G, and PXA-B may have a stripe arrangement or a Diamond Pixel® arrangement. PENTILE® is a registered trademark of Samsung Display Co., Ltd., Republic of Korea.

The first to third emissive areas PXA-R, PXA-G, and PXA-B may have various shapes when viewed from above the plane (e.g., in a plan view). For example, the first to third emissive areas PXA-R, PXA-G, and PXA-B may have a polygonal, circular, or oval shape. FIG. 4 illustrates the first and third emissive areas PXA-R and PXA-B that have a quadrangular shape (or, a rhombic shape) when viewed from above the plane and the second emissive areas PXA-G that have an octagonal shape when viewed from above the plane.

When viewed from above the plane, the first to third emissive areas PXA-R, PXA-G, and PXA-B may have the same shape, or at least some of the first to third emissive areas PXA-R, PXA-G, and PXA-B may have different shapes. FIG. 4 illustrates the first and third emissive areas PXA-R and PXA-B that have the same shape when viewed from above the plane and the second emissive areas PXA-G that have a shape different from those of the first and third emissive areas PXA-R and PXA-B when viewed from above the plane.

At least some of the first to third emissive areas PXA-R, PXA-G, and PXA-B may have different areas when viewed from above the plane. In one or more embodiments, the area of the first emissive area PXA-R emitting red light may be greater than the area of the second emissive area PXA-G emitting green light and may be smaller than the area of the third emissive area PXA-B emitting blue light. However, the relative size relationship between the first to third emissive areas PXA-R, PXA-G, and PXA-B depending on the colors of emitted light is not limited thereto and may vary depending on the design of the display module DM (refer to FIG. 2). Furthermore, without being limited thereto, the first to third emissive areas PXA-R, PXA-G, and PXA-B may have the same area when viewed from above the plane.

In one or more embodiments, the shapes, areas, and arrangement of the first to third emissive areas PXA-R, PXA-G, and PXA-B of the display module DM (refer to FIG. 2) of the present disclosure may be designed in various ways depending on the colors of emitted light or the size and configuration of the display module DM (refer to FIG. 2) and are not limited to the embodiment illustrated in FIG. 4.

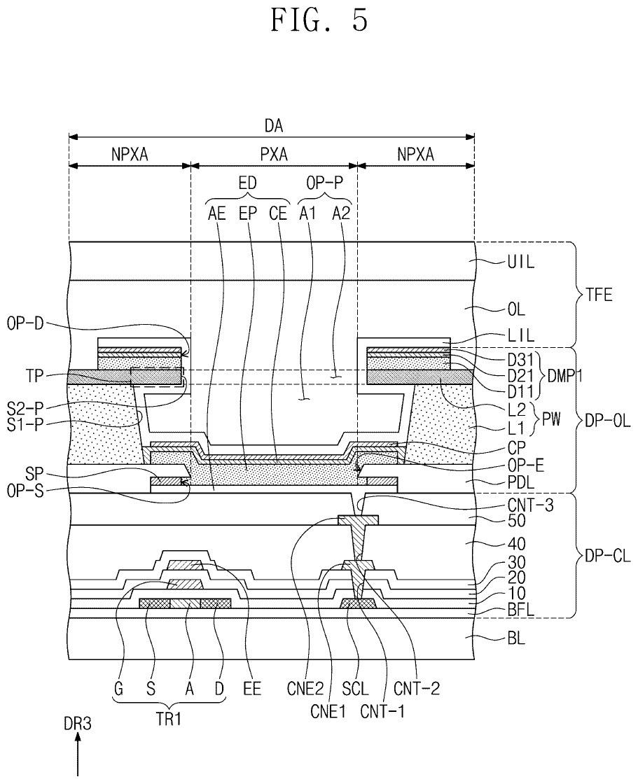

FIG. 5 is an enlarged sectional view of a portion of the display area of the display panel according to one or more embodiments of the present disclosure. FIG. 5 is an enlarged view of one emissive area PXA in the display area DA (refer to FIG. 4), and the emissive area PXA of FIG. 5 may correspond to one of the first to third emissive areas PXA-R, PXA-G, and PXA-B of FIG. 4.

Referring to FIG. 5, the display panel DP may include the base layer BL, the circuit element layer DP-CL, the display element layer DP-OL, and the thin film encapsulation layer TFE.

The display panel DP may include a plurality of insulating layers, a semiconductor pattern, a conductive pattern, and a signal line. An insulating layer, a semiconductor layer, and a conductive layer are formed by coating, deposition, and/or the like. Thereafter, the insulating layer, the semiconductor layer, and the conductive layer may be selectively subjected to patterning by photolithography and etching. The semiconductor pattern, the conductive pattern, and the signal line included in the circuit element layer DP-CL and the display element layer DP-OL may be formed by the above-described method.

The circuit element layer DP-CL may be disposed on the base layer BL. The circuit element layer DP-CL may include a buffer layer BFL, a transistor TR1, a signal transmission area SCL, first to fifth insulating layers 10, 20, 30, 40, and 50, an electrode EE, and a plurality of connecting electrodes CNE1 and CNE2.

The buffer layer BFL may be disposed on the base layer BL. The buffer layer BFL may improve the coupling force between the base layer BL and a semiconductor pattern. The buffer layer BFL may include silicon oxide layers and/or silicon nitride layers. The silicon oxide layers and the silicon nitride layers may be alternately stacked one above another.

The semiconductor pattern may be disposed on the buffer layer BFL. The semiconductor pattern may include poly-silicon. However, without being limited thereto, the semiconductor pattern may include amorphous silicon or metal oxide. FIG. 5 illustrates only a portion of the semiconductor pattern, and the semiconductor pattern may be additionally disposed in the plurality of emissive areas PXA-R, PXA-G, and PXA-B (refer to FIG. 4). The semiconductor pattern may be arranged across the plurality of emissive areas PXA-R, PXA-G, and PXA-B (refer to FIG. 4) according to a specific rule. The semiconductor pattern may have different electrical properties depending on whether doping is performed or not. The semiconductor pattern may include first areas having a high doping concentration and a second area having a low doping concentration. The first areas may be doped with an N-type dopant or a P-type dopant. A P-type transistor may include first areas doped with a P-type dopant.

The first areas have a higher conductivity than the second area and substantially serve as an electrode or a signal line. The second area may substantially correspond to an active (or, channel) area of the transistor. In other words, one portion of the semiconductor pattern may be the active area of the transistor, another portion may be a source or a drain of the transistor, and the other portion may be a conductive area.

The source S, the active area A, and the drain D of the transistor TR1 may be formed from the semiconductor pattern. A portion of the signal transmission area SCL formed from the semiconductor pattern is illustrated in FIG. 5. In one or more embodiments, the signal transmission area SCL may be connected to the drain D of the transistor TR1 when viewed from above the plane.

The first to fifth insulating layers 10, 20, 30, 40, and 50 may be disposed on the buffer layer BFL. The first to fifth insulating layers 10 to 50 may be inorganic layers and/or organic layers.

The first insulating layer 10 may be disposed on the buffer layer BFL to cover the source S, the active area A, and the drain D of the transistor TR1 and the signal transmission area SCL. A gate G may be disposed on the first insulating layer 10. The second insulating layer 20 may be disposed on the first insulating layer 10 and may cover the gate G. The electrode EE may be disposed on the second insulating layer 20. The third insulating layer 30 may be disposed on the second insulating layer 20 and may cover the electrode EE.

The first connecting electrode CNE1 may be disposed on the third insulating layer 30. The first connecting electrode CNE1 may be connected to the signal transmission area SCL through a contact hole CNT-1 penetrating the first to third insulating layers 10, 20, and 30. The fourth insulating layer 40 may be disposed on the third insulating layer 30 and may cover the first connecting electrode CNE1. The fourth insulating layer 40 may be an organic layer.

The second connecting electrode CNE2 may be disposed on the fourth insulating layer 40. The second connecting electrode CNE2 may be connected to the first connecting electrode CNE1 through a contact hole CNT-2 penetrating the fourth insulating layer 40. The fifth insulating layer 50 may be disposed on the fourth insulating layer 40 and may cover the second connecting electrode CNE2. The fifth insulating layer 50 may be an organic layer.

The display element layer DP-OL may be disposed on the circuit element layer DP-CL. The display element layer DP-OL may include a light emitting element ED, a sacrificial pattern SP, a pixel defining layer PDL, a barrier wall PW, and a first dummy pattern DMP1.

The light emitting element ED may include an anode AE (or, a first electrode), an emission pattern EP, and a cathode CE (or, a second electrode). Each of the above-described first to third light emitting elements may include substantially the same configuration as the light emitting element ED of FIG. 5. Description of the anode AE, the emission pattern EP, and the cathode CE may be identically applied to the anodes, the emission patterns, and the cathodes of the first to third light emitting elements.

The anode AE may be disposed on the fifth insulating layer 50 of the circuit element layer DP-CL. The anode AE may be a transmissive electrode, a transflective electrode, and/or a reflective electrode. The anode AE may have conductivity. For example, as long as the anode AE is capable of having conductivity, the anode AE may be formed of various materials such as metal, transparent conductive oxide (TCO), and/or a conductive polymer material.

The anode AE may be connected to the second connecting electrode CNE2 by a connection contact hole CNT-3 defined to penetrate the fifth insulating layer 50. Accordingly, the anode AE may be electrically connected to the signal transmission area SCL through the first and second connecting electrodes CNE1 and CNE2 and may be electrically connected to a corresponding circuit element.

The sacrificial pattern SP may be disposed on the upper surface of the anode AE. A sacrificial opening OP-S that exposes a portion of the upper surface of the anode AE may be defined in the sacrificial pattern SP. The sacrificial pattern SP may include amorphous transparent conductive oxide.

The pixel defining layer PDL may be disposed on the fifth insulating layer 50 of the circuit element layer DP-CL. The pixel defining layer PDL may have a light emitting opening OP-E defined therein. The light emitting opening OP-E may overlap the anode AE, and the pixel defining layer PDL may expose at least a portion of the anode AE through the light emitting opening OP-E.

The light emitting opening OP-E may correspond to the sacrificial opening OP-S of the sacrificial pattern SP. According to this embodiment, the upper surface of the anode AE may be spaced (e.g., spaced apart) from the pixel defining layer DPL on the section with the sacrificial pattern SP therebetween. Accordingly, damage to the anode AE in the process of forming the light emitting opening OP-E may be prevented.

When viewed from above the plane, the area of the light emitting opening OP-E may be smaller than the area of the sacrificial opening OP-S. That is, the inner surface of the pixel defining layer PDL that defines the light emitting opening OP-E may be closer to the center of the anode AE than the inner surface of the sacrificial pattern SP that defines the sacrificial opening OP-S. However, without being limited thereto, the inner surface of the sacrificial pattern SP that defines the sacrificial opening OP-S may be substantially aligned with the inner surface of the pixel defining layer PDL that defines the corresponding light emitting opening OP-E. In this case, the emissive area PXA may be an area of the anode AE exposed from the corresponding sacrificial opening OP-S.

The pixel defining layer PDL may include an inorganic insulating material. For example, the pixel defining layer PDL may include silicon nitride SiNₓ. The pixel defining layer PDL may be disposed between the anode AE and the barrier wall PW and may block electrical connection between the anode AE and the barrier wall PW.

The barrier wall PW may be disposed on the pixel defining layer PDL. The barrier wall PW may have a barrier wall opening OP-P defined therein. The barrier wall opening OP-P may correspond to the light emitting opening OP-E and may expose at least a portion of the anode AE.

The barrier wall PW may have an undercut shape on the section. The barrier wall PW may include multiple layers sequentially stacked one above another, and at least one layer from among the multiple layers may be recessed relative to layers stacked adjacent thereto. Accordingly, the barrier wall PW may include a tip portion TP.

In this embodiment, the barrier wall PW may include a first barrier wall layer L1 and a second barrier wall layer L2. The first barrier wall layer L1 may be disposed on the pixel defining layer PDL, and the second barrier wall layer L2 may be disposed on the first barrier wall layer L1. The first barrier wall layer L1 may have a first conductivity, and the second barrier wall layer L2 may have a second conductivity lower than the first conductivity. The first barrier wall layer L1 may be thicker than the second barrier wall layer L2. The first barrier wall layer L1 may have a higher etch rate than the second barrier wall layer L2.

In this embodiment, the first barrier wall layer L1 may be relatively recessed with respect to the emissive area PXA when compared to the second barrier wall layer L2. That is, the first barrier wall layer L1 may be undercut with respect to the second barrier wall layer L2. The barrier wall opening OP-P defined in the barrier wall PW may include a first opening area A1 and a second opening area A2 sequentially arranged along the third direction DR3. The first barrier wall layer L1 may include a first inner surface S1-P that defines the first opening area A1 of the barrier wall opening OP-P, and the second barrier wall layer L2 may include a second inner surface S2-P that defines the second opening area A2 of the barrier wall opening OP-P.

The first inner surface S1-P of the first barrier wall layer L1 may be relatively recessed inward with respect to the emissive area PXA when compared to the second inner surface S2-P of the second barrier wall layer L2. The portion of the second barrier wall layer L2 that protrudes from the first barrier wall layer L1 toward the emissive area PXA may define the tip portion TP.

FIG. 5 illustrates an example that the first and second inner surfaces S1-P and S2-P are perpendicular to the upper surface of the pixel defining layer PDL. However, without being limited thereto, the barrier wall PW may have a tapered shape, or may have an inverted tapered shape.

The emission pattern EP may be disposed on the anode AE. The emission pattern EP may include an emissive layer including a luminescent material. The emission pattern EP may further include a hole injection layer (HIL) and a hole transport layer (HTL) that are disposed between the anode AE and the emissive layer and may further include an electron transport layer (ETL) and an electron injection layer (EIL) that are disposed on the emissive layer. The emission pattern EP may be referred to as an “organic layer” or an “intermediate layer”.

The emission pattern EP may be subjected to patterning by the tip portion TP defined in the barrier wall PW. The emission pattern EP may be disposed in the sacrificial opening OP-S, the light emitting opening OP-E, and the barrier wall opening OP-P. The emission pattern EP may cover a portion of the upper surface of the pixel defining layer PDL exposed from the barrier wall opening OP-P.

The cathode CE may be disposed on the emission pattern EP. The cathode CE may be subjected to patterning by the tip portion TP defined in the barrier wall PW. The cathode CE may make contact with the first inner surface S1-P of the first barrier wall layer L1. The cathode CE may have conductivity. For example, as long as the cathode CE is capable of having conductivity, the cathode CE may be formed of various materials such as metal, transparent conductive oxide (TCO), and/or a conductive polymer material.

The barrier wall PW may receive a bias voltage (or, a common voltage). Accordingly, the cathode CE may be electrically connected to the barrier wall PW and may receive the bias voltage (or, the common voltage) from the barrier wall PW.

FIG. 5 illustrates an example that the emission pattern EP does not make contact with the first inner surface S1-P of the first barrier wall layer L1. However, without being limited thereto, the emission pattern EP, together with the cathode CE, may make contact with the first inner surface S1-P of the first barrier wall layer L1.

According to one or more embodiments of the present disclosure, the display panel DP may further include a capping pattern CP. The capping pattern CP may be disposed in the barrier wall opening OP-P and may be disposed on the cathode CE. The capping pattern CP may be subjected to patterning by the tip portion TP formed in the barrier wall PW.

FIG. 5 illustrates an example that the capping pattern CP does not make contact with the first inner surface S1-P of the first barrier wall layer L1. However, without being limited thereto, the capping pattern CP may be formed to make contact with the first inner surface S1-P of the first barrier wall layer L1. According to one or more embodiments of the present disclosure, the capping pattern CP may be omitted.

The first dummy pattern DMP1 may be disposed on the barrier wall PW. The first dummy pattern DMP1 may include a first-first layer dummy pattern D11, a second-first layer dummy pattern D21, and a third-first layer dummy pattern D31. The first-first layer dummy pattern D11, the second-first layer dummy pattern D21, and the third-first layer dummy pattern D31 may be sequentially stacked on the upper surface of the second barrier wall layer L2 of the barrier wall PW in the third direction DR3.

The first-first layer dummy pattern D11 may include an organic material. For example, the first-first layer dummy pattern D11 may include the same material as the emission pattern EP. The first-first layer dummy pattern D11 may be concurrently (e.g., simultaneously) formed with the emission pattern EP through one process and may be separated from the emission pattern EP by the undercut shape of the barrier wall PW.

The second-first layer dummy pattern D21 may include a conductive material. For example, the second-first layer dummy pattern D21 may include the same material as the cathode CE. The second-first layer dummy pattern D21 may be concurrently (e.g., simultaneously) formed with the cathode CE through one process and may be separated from the cathode CE by the undercut shape of the barrier wall PW.

The third-first layer dummy pattern D31 may include the same material as the capping pattern CP. The third-first layer dummy pattern D31 may be concurrently (e.g., simultaneously) formed with the capping pattern CP through one process and may be separated from the capping pattern CP by the undercut shape of the barrier wall PW.

A dummy opening OP-D (e.g., see FIG. 6) may be defined in the first dummy pattern DMP1. The dummy opening OP-D (e.g., see FIG. 6) may overlap the light emitting opening OP-E. The dummy opening OP-D may include an area (or, a first-first dummy area) defined by the inner surface of the first-first layer dummy pattern D11, an area (or, a second-first dummy area) defined by the inner surface of the second-first layer dummy pattern D21, and an area (or, a third-first dummy area) defined by the inner surface of the third-first layer dummy pattern D31. Each of the first-first layer dummy pattern D11, the second-first layer dummy pattern D21, and the third-first layer dummy pattern D31, when viewed from above the plane, may have a closed-line shape surrounding the emissive area PXA.

FIG. 5 illustrates an example that the inner surfaces of the first-first to third-first layer dummy patterns D11, D21, and D31 are aligned with the second inner surface S2-P of the second barrier wall layer L2. However, the present disclosure is not limited thereto, and the first-first to third-first layer dummy patterns D11, D21, and D31 may cover the second inner surface S2-P of the second barrier wall layer L2.

The thin film encapsulation layer TFE may be disposed on the display element layer DP-OL. The thin film encapsulation layer TFE may include a lower inorganic encapsulation pattern LIL, an organic encapsulation film OL, and an upper inorganic encapsulation film UIL.

The lower inorganic encapsulation pattern LIL may correspond to the light emitting opening OP-E. The lower inorganic encapsulation pattern LIL may cover the light emitting element ED and the first dummy pattern DMP1, and a portion of the lower inorganic encapsulation pattern LIL may be disposed in the barrier wall opening OP-P. According to one or more embodiments, the lower inorganic encapsulation pattern LIL may be brought into contact with the first inner surface S1-P of the first barrier wall layer L1.

The organic encapsulation film OL may cover the lower inorganic encapsulation pattern LIL and may provide a flat upper surface. The upper inorganic encapsulation film UIL may be disposed on the organic encapsulation film OL.

The lower inorganic encapsulation pattern LIL and the upper inorganic encapsulation film UIL may protect the display element layer DP-OL from moisture and/or oxygen, and the organic encapsulation film OL may protect the display element layer DP-OL from foreign matter such as dust particles.

FIG. 6 is a sectional view of the display panel taken along the line I-I′ of FIG. 4 according to one or more embodiments of the present disclosure. FIG. 6 is an enlarged view illustrating one first emissive area PXA-R, one second emissive area PXA-G, and one third emissive area PXA-B, and the description of the emissive area PXA of FIG. 5 may be identically applied to the first to third emissive areas PXA-R, PXA-G, and PXA-B.

Referring to FIG. 6, the display panel DP according to this embodiment may include the base layer BL, the circuit element layer DP-CL, the display element layer DP-OL, and the thin film encapsulation layer TFE. The display element layer DP-OL may include the light emitting elements ED1, ED2, and ED3, sacrificial patterns SP1, SP2, and SP3, the pixel defining layer PDL, the barrier wall PW, and the first dummy pattern DMP1.

The light emitting elements ED1, ED2, and ED3 may include the first light emitting element ED1, the second light emitting element ED2, and the third light emitting element ED3. The first light emitting element ED1 may include a first anode AE1, a first emission pattern EP1, and a first cathode CE1. The second light emitting element ED2 may include a second anode AE2, a second emission pattern EP2, and a second cathode CE2. The third light emitting element ED3 may include a third anode AE3, a third emission pattern EP3, and a third cathode CE3. The first to third anodes AE1, AE2, and AE3 may be provided in a plurality of patterns. In one or more embodiments, the first emission pattern EP1 may provide red light, the second emission pattern EP2 may provide green light, and the third emission pattern EP3 may provide blue light.

First to third light emitting openings OP1-E, OP2-E, and OP3-E may be defined in the pixel defining layer PDL. The first light emitting opening OP1-E may expose at least a portion of the first anode AE1. The first emissive area PXA-R may be defined as an area of the upper surface of the first anode AE1 that is exposed by the first light emitting opening OP1-E. The second light emitting opening OP2-E may expose at least a portion of the second anode AE2. The second emissive area PXA-G may be defined as an area of the upper surface of the second anode AE2 that is exposed by the second light emitting opening OP2-E. The third light emitting opening OP3-E may expose at least a portion of the third anode AE3. The third emissive area PXA-B may be defined as an area of the upper surface of the third anode AE3 that is exposed by the third light emitting opening OP3-E.

The sacrificial patterns SP1, SP2, and SP3 may include the first sacrificial pattern SP1, the second sacrificial pattern SP2, and the third sacrificial pattern SP3. The first to third sacrificial patterns SP1, SP2, and SP3 may be disposed on the upper surfaces of the first to third anodes AE1, AE2, and AE3, respectively. First to third sacrificial openings OP1-S, OP2-S, and OP3-S corresponding to the first to third light emitting openings OP1-E, OP2-E, and OP3-E may be defined in the first to third sacrificial patterns SP1, SP2, and SP3, respectively.

In this embodiment, first to third barrier wall openings OP1-P, OP2-P, and OP3-P corresponding to the first to third light emitting openings OP1-E, OP2-E, and OP3-E, respectively, may be defined in the barrier wall PW.

Each of the first to third barrier wall openings OP1-P, OP2-P, and OP3-P may include the first opening area A1 (refer to FIG. 5) and the second opening area A2 (refer to FIG. 5) described above with reference to FIG. 5. The first barrier wall layer L1 may include the first inner surfaces S1-P (refer to FIG. 5) that define the first opening areas A1 (refer to FIG. 5) of the first to third barrier wall openings OP1-P, OP2-P, and OP3-P. The second barrier wall layer L2 may include the second inner surfaces S2-P (refer to FIG. 5) that define the second opening areas A2 (refer to FIG. 5) of the first to third barrier wall openings OP1-P, OP2-P, and OP3-P.

The first emission pattern EP1 and the first cathode CE1 may be disposed in the first barrier wall opening OP1-P, the second emission pattern EP2 and the second cathode CE2 may be disposed in the second barrier wall opening OP2-P, and the third emission pattern EP3 and the third cathode CE3 may be disposed in the third barrier wall opening OP3-P. Each of the first to third cathodes CE1, CE2, and CE3 may make contact with the first inner surface S1-P of a corresponding barrier wall opening from among the first to third barrier wall openings OP1-P, OP2-P, and OP3-P.

In this embodiment, the first to third cathodes CE1, CE2, and CE3 may be physically separated by the second barrier wall layer L2 that forms the tip portions TP and may be formed in the respective light emitting openings OP1-E, OP2-E, and OP3-E. The first to third cathodes CE1, CE2, and CE3 may make contact with the first barrier wall layer L1 and may be electrically connected with the first barrier wall layer L1 to receive the common voltage. The first barrier wall layer L1 in contact with the first to third cathodes CE1, CE2, and CE3 may have a higher electrical conductivity than the second barrier wall layer L2 and thus may decrease contact resistance with the first to third cathodes CE1, CE2, and CE3. Accordingly, a common cathode voltage may be uniformly provided for the emissive areas PXA-R, PXA-G, and PXA-B.

According to the present disclosure, the plurality of emission patterns EP1, EP2, and EP3 may be subjected to patterning and deposited in pixel units by the tip portions defined in the barrier wall PW. That is, the plurality of emission patterns EP1, EP2, and EP3 may be commonly formed using an open mask, but may be easily divided in pixel units by the barrier wall PW.

In contrast, when the plurality of emission patterns EP1, EP2, and EP3 are subjected to patterning using a fine metal mask (FMM), a support spacer protruding from a conductive barrier wall has to be provided to support the fine metal mask. Furthermore, the fine metal mask may be spaced, by the height of the barrier wall and the spacer, apart from a base surface on which the patterning is performed, and therefore there may be a limitation in the implementation of high resolution. In addition, because the fine metal mask is brought into contact with the spacer, foreign matter may remain on the spacer after the patterning process of the plurality of emission patterns EP1, EP2, and EP3, or the spacer may be damaged by a dent in the fine metal mask. Accordingly, a defective display panel may be formed.

According to this embodiment, because the barrier wall PW is included, the physical separation between the light emitting elements ED1, ED2, and ED3 may be easily achieved. Accordingly, current leakage or a driving error between the adjacent emissive areas PXA-R, PXA-G, and PXA-B may be prevented, and the light emitting elements ED1, ED2, and ED3 may be independently driven.

In particular, the plurality of emission patterns EP1, EP2, and EP3 may be subjected to patterning without a mask in contact with an internal component in the display area DA (refer to FIG. 1B). Accordingly, a defect rate may be reduced, and thus the display panel DP with improved process reliability may be provided. Because the patterning is possible even without the separate support spacer protruding from the barrier wall PW, the areas of the emissive areas PXA-R, PXA-G, and PXA-B may be scaled down, and thus the display panel DP capable of easily implementing high resolution may be provided.

Furthermore, during the manufacturing process of the large-area display panel DP, a large-area mask may be omitted. Accordingly, process costs may be reduced, and the display panel DP may not be affected by defects that are likely to occur in the large-area mask. Thus, the display panel DP with improved process reliability may be provided.

Capping patterns CP1, CP2, and CP3 may include the first capping pattern CP1, the second capping pattern CP2, and the third capping pattern CP3. The first to third capping patterns CP1, CP2, and CP3 may be disposed on the first to third cathodes CE1, CE2, and CE3, respectively, and may be disposed in the first to third barrier wall openings OP1-P, OP2-P, and OP3-P, respectively.

The first dummy pattern DMP1 may include a first-first dummy pattern DMP11, a first-second dummy pattern DMP12, and a first-third dummy pattern DMP13. The first-first dummy pattern DMP11, the first-second dummy pattern DMP12, and the first-third dummy pattern DMP13 may include first-first layer dummy patterns D11a, D11b, and D11c, second-first layer dummy patterns D21a, D21b, and D21c, and third-first layer dummy patterns D31a, D31b, and D31c.

The first-first dummy pattern DMP11 may include the first-first to third-first layer dummy patterns D11a, D21a, and D31a that are around (e.g., that surround) the first emissive area PXA-R when viewed from above the plane. The first-first layer dummy pattern D11a of the first-first dummy pattern DMP11 may include the same material as the first emission pattern EP1 and may be formed through the same process as that of the first emission pattern EP1. The second-first layer dummy pattern D21a of the first-first dummy pattern DMP11 may include the same material as the first cathode CE1 and may be formed through the same process as that of the first cathode CE1. The third-first layer dummy pattern D31a of the first-first dummy pattern DMP11 may include the same material as the first capping pattern CP1 and may be formed through the same process as that of the first capping pattern CP1.

The first-second dummy pattern DMP12 may include the first-first to third-first layer dummy patterns D11b, D21b, and D31b that are around (e.g., that surround) the second emissive area PXA-G when viewed from above the plane. The first-first layer dummy pattern D11b of the first-second dummy pattern DMP12 may include the same material as the second emission pattern EP2 and may be formed through the same process as that of the second emission pattern EP2. The second-first layer dummy pattern D21b of the first-second dummy pattern DMP12 may include the same material as the second cathode CE2 and may be formed through the same process as that of the second cathode CE2. The third-first layer dummy pattern D31b of the first-second dummy pattern DMP12 may include the same material as the second capping pattern CP2 and may be formed through the same process as that of the second capping pattern CP2.

The first-third dummy pattern DMP13 may include the first-first to third-first layer dummy patterns D11c, D21c, and D31c that are around (e.g., that surround) the third emissive area PXA-B when viewed from above the plane. The first-first layer dummy pattern D11c of the first-third dummy pattern DMP13 may include the same material as the third emission pattern EP3 and may be formed through the same process as that of the third emission pattern EP3. The second-first layer dummy pattern D21c of the first-third dummy pattern DMP13 may include the same material as the third cathode CE3 and may be formed through the same process as that of the third cathode CE3. The third-first layer dummy pattern D31c of the first-third dummy pattern DMP13 may include the same material as the third capping pattern CP3 and may be formed through the same process as that of the third capping pattern CP3.

First to third dummy openings OP1-D, OP2-D, and OP3-D overlapping the first to third light emitting openings OP1-E, OP2-E, and OP3-E, respectively, may be defined in the first dummy pattern DMP1. The first dummy opening OP1-D may be defined by the inner surfaces of the first-first to third-first layer dummy patterns D11a, D21a, and D31a of the first-first dummy pattern DMP11, the second dummy opening OP2-D may be defined by the inner surfaces of the first-second to third-second layer dummy patterns D11b, D21b, and D31b of the first-second dummy pattern DMP12, and the third dummy opening OP3-D may be defined by the inner surfaces of the first-third to third-third layer dummy patterns D11c, D21c, and D31c of the first-third dummy pattern DMP13.

The thin film encapsulation layer TFE may include lower inorganic encapsulation patterns LIL1, LIL2, and LIL3, the organic encapsulation film OL, and the upper inorganic encapsulation film UIL. In this embodiments, the lower inorganic encapsulation patterns LIL1, LIL2, and LIL3 may include the first lower inorganic encapsulation pattern LIL1, the second lower inorganic encapsulation pattern LIL2, and the third lower inorganic encapsulation pattern LIL3. The first to third lower inorganic encapsulation patterns LIL1, LIL2, and LIL3 may correspond to the first to third light emitting openings OP1-E, OP2-E, and OP3-E, respectively.

The first lower inorganic encapsulation pattern LIL1 may cover the first light emitting element ED1 and the first-first dummy pattern DMP11 and may be partially disposed in the first barrier wall opening OP1-P. The second lower inorganic encapsulation pattern LIL2 may cover the second light emitting element ED2 and the first-second dummy pattern DMP12 and may be partially disposed in the second barrier wall opening OP2-P. The third lower inorganic encapsulation pattern LIL3 may cover the third light emitting element ED3 and the first-third dummy pattern DMP13 and may be partially disposed in the third barrier wall opening OP3-P. The first to third lower inorganic encapsulation patterns LIL1, LIL2, and LIL3 may be provided in the form of patterns that are spaced (e.g., spaced apart) from one another.

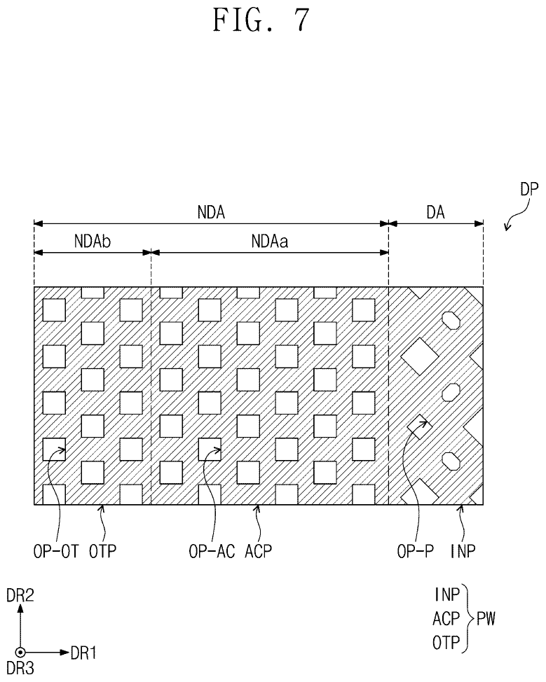

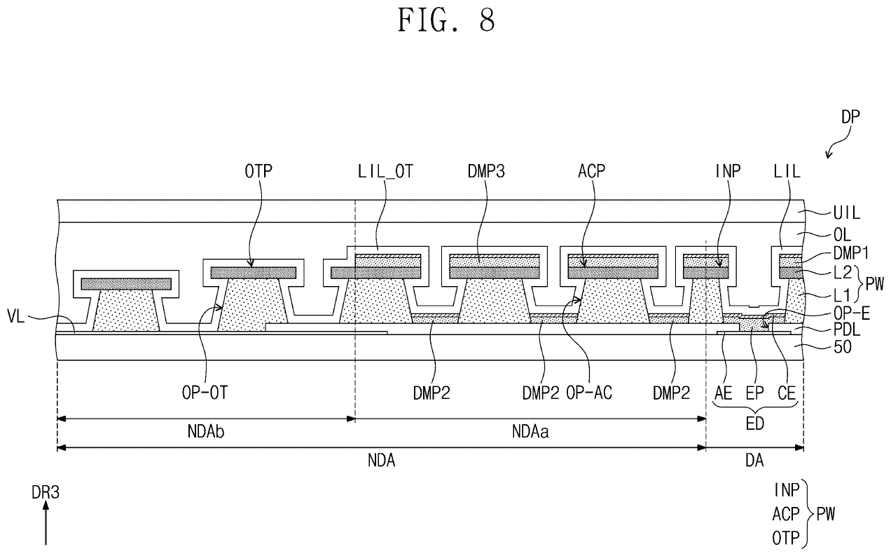

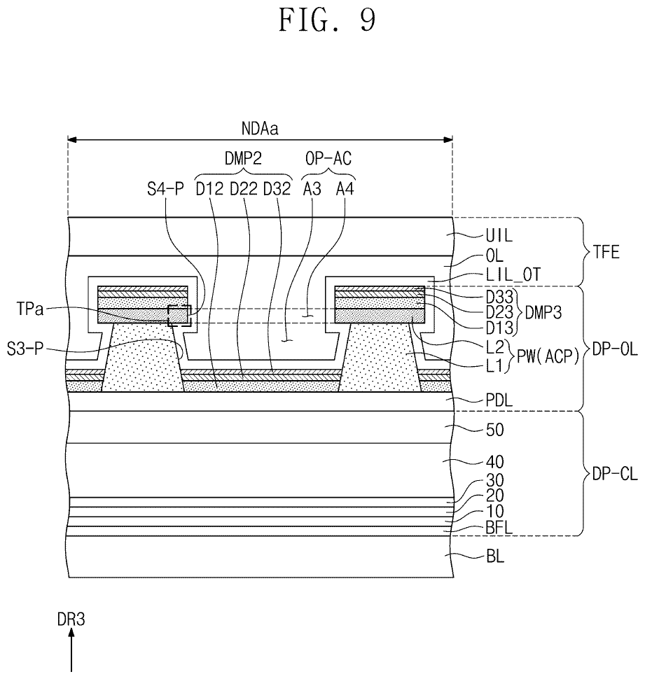

FIG. 7 is an enlarged plan view of a partial region of the display panel according to one or more embodiments of the present disclosure. FIG. 8 is an enlarged sectional view of a portion of the display area and a portion of the non-display area of the display panel according to one or more embodiments of the present disclosure. FIG. 9 is an enlarged sectional view of a portion of a first non-display area of the display panel according to one or more embodiments of the present disclosure.

Referring to FIGS. 7-9, the display panel DP may include the display area DA and the non-display area NDA. According to this embodiment, the non-display area NDA may include the first non-display area NDAa and the second non-display area NDAb. The first non-display area NDAa may be adjacent to the display area DA, and the second non-display area NDAb may be spaced (e.g., spaced apart) from the display area DA with the first non-display area NDAa therebetween. The first non-display area NDAa may be located between the display area DA and the second non-display area NDAb. The first non-display area NDAa may be referred to as a deposition area or an anchor area. The second non-display area NDAb may be referred to as a connection area.

The first non-display area NDAa may be an area of the non-display area NDA where a material included in the emission pattern EP is deposited in the process of forming the emission pattern EP. In the process of forming the emission pattern EP, the material included in the emission pattern EP may be deposited on the display area DA and the first non-display area NDAa. An anchor may be disposed in the first non-display area NDAa. The anchor may be provided in various forms, and detailed description of the anchor will be given below.

The second non-display area NDAb may be the remaining area of the non-display area NDA other than the first non-display area NDAa. In the process of forming the emission pattern EP, the material included in the emission pattern EP may not be deposited on the second non-display area NDAb.

The barrier wall PW may also overlap the non-display area NDA. The barrier wall PW may extend from the display area DA to the portion of the non-display area NDA where a driving voltage line VL is disposed. The driving voltage line VL may receive the bias voltage (or, the common voltage).

The barrier wall PW may include an inner portion INP and an outer portion OTP. The inner portion INP may be disposed in the display area DA, and the outer portion OTP may be disposed in the second non-display area NDAb. In this embodiment, the barrier wall PW may further include an anchor portion ACP. The anchor portion ACP may be disposed in the first non-display area NDAa. The anchor portion ACP may be located between the inner portion INP and the outer portion OTP. The inner portion INP, the anchor portion ACP, and the outer portion OTP may form a one-body shape. The anchor may be provided from the anchor portion ACP of the barrier wall PW.

In one or more embodiments, the barrier wall PW may not include the anchor portion ACP, and the anchor may be provided by a separate component. In this case, the barrier wall PW may further include a connecting portion, and the connecting portion may be disposed in the first non-display area NDAa and may be spaced (e.g., spaced apart) from the anchor. The inner portion INP, the connecting portion, and the outer portion OTP may form a one-body shape, and the connecting portion may connect the inner portion INP and the outer portion OTP.

In the second non-display area NDAb, the outer portion OTP of the barrier wall PW may be connected to the driving voltage line VL. The pixel defining layer PDL may not be disposed in at least a portion of the second non-display area NDAb. Accordingly, at least a portion of the driving voltage line VL may be exposed from the pixel defining layer PDL and may be connected to the barrier wall PW. The barrier wall PW may receive the bias voltage (or, the common voltage) through the driving voltage line VL.

FIG. 8 illustrates an example that the driving voltage line VL is disposed on the fifth insulating layer 50 and the barrier wall PW is directly connected to the driving voltage line VL. However, the present disclosure is not limited thereto. In one or more embodiments of the present disclosure, an auxiliary electrode may be provided on the fifth insulating layer 50, and the driving voltage line VL may be disposed on one of the first to fourth insulating layers 10 to 40 and may be connected with the auxiliary electrode through a contact hole. In this case, the barrier wall PW may be connected to the auxiliary electrode and may be electrically connected to the driving voltage line VL through the auxiliary electrode.

Barrier wall openings OP-P may be defined in the inner portion INP of the barrier wall PW.

Outer openings OP-OT may be defined in the outer portion OTP of the barrier wall PW. Although FIG. 7 illustrates an example that the outer openings OP-OT have a square shape when viewed from above the plane, the shape of the outer openings OP-OT on the plane is not limited to any one embodiment.

The anode AE may not be disposed in the non-display area NDA. Openings for exposing at least a portion of the anode AE may not be defined in the pixel defining layer PDL in the first non-display area NDAa.

Anchor openings OP-AC may be defined in the anchor portion ACP of the barrier wall PW. The anchor openings OP-AC may not overlap the anode AE. A portion of the upper surface of the pixel defining layer PDL may be exposed from the anchor portion ACP of the barrier wall PW by the anchor openings OP-AC.

In one or more embodiments, as illustrated in FIG. 7, the anchor openings OP-AC may be spaced (e.g., spaced apart) from one another. For example, the anchor openings OP-AC may be arranged in a matrix (or, lattice) form. Although FIG. 7 illustrates an example that the anchor openings OP-AC have a square shape when viewed from above the plane, the shape of the anchor openings OP-AC on the plane is not limited to any one embodiment.

As illustrated in FIGS. 8 and 9, the anchor portion ACP may have an undercut shape on the section. The barrier wall PW may include multiple layers sequentially stacked one above another, and at least one layer from among the multiple layers may be recessed relative to layers stacked adjacent thereto within the anchor portion ACP. Accordingly, the anchor portion ACP may include a tip portion TPa.

In one or more embodiments, the anchor openings OP-AC may be formed by the same process as that of the barrier wall openings OP-P. The etch rate of the first barrier wall layer L1 may be greater than the etch rate of the second barrier wall layer L2. Accordingly, within the anchor portion ACP, the first barrier wall layer L1 may have a shape recessed relative to the second barrier wall layer L2. That is, within the anchor portion ACP, the first barrier wall layer L1 may be undercut with respect to the second barrier wall layer L2. The anchor opening OP-AC defined in the barrier wall PW may include a third opening area A3 and a fourth opening area A4 sequentially arranged along the third direction DR3. The first barrier wall layer L1 may include a third inner surface S3-P that defines the third opening area A3 of the anchor opening OP-AC, and the second barrier wall layer L2 may include a fourth inner surface S4-P that defines the fourth opening area A4 of the anchor opening OP-AC. The third inner surface S3-P of the first barrier wall layer L1 may be recessed inward (or, in the direction toward the inside of the anchor portion ACP) relative to the fourth inner surface S4-P of the second barrier wall layer L2. The portion of the second barrier wall layer L2 that protrudes from the first barrier wall layer L1 within the anchor portion ACP may define the tip portion TPa.

The display panel DP may further include a second dummy pattern DMP2 and a third dummy pattern DMP3. The second dummy pattern DMP2 and the third dummy pattern DMP3 may be disposed in the first non-display area NDAa.

In this embodiment, a plurality of second dummy patterns DMP2 may be provided. The plurality of second dummy patterns DMP2 may be spaced (e.g., spaced apart) from one another. The second dummy patterns DMP2 may be disposed in the anchor openings OP-AC, respectively. The second dummy patterns DMP2 may be directly disposed on the pixel defining layer PDL. The third dummy pattern DMP3 may be disposed on the anchor portion ACP. That is, the third dummy pattern DMP3 may be disposed on the portion of the barrier wall PW disposed in the first non-display area NDAa. In one or more embodiments of the present disclosure, the third dummy pattern DMP3 may have a one-body shape with the first dummy pattern DMP1 in the display area DA.

Each of the second dummy patterns DMP2 may include first-second to third-second layer dummy patterns D12, D22, and D32. The first-second to third-second layer dummy patterns D12, D22, and D32 may be sequentially stacked on the upper surface of the pixel defining layer PDL in the third direction DR3. The third dummy pattern DMP3 may include first-third to third-third layer dummy patterns D13, D23, and D33. The first-third to third-third layer dummy patterns D13, D23, and D33 may be sequentially stacked on the upper surface of the barrier wall PW in the third direction DR3.

Each of the first-second layer dummy pattern D12 and the first-third layer dummy pattern D13 may include an organic material. For example, each of the first-second layer dummy pattern D12 and the first-third layer dummy pattern D13 may include the same material as the emission pattern EP. The first-second layer dummy pattern D12 and the first-third layer dummy pattern D13 may be concurrently (e.g., simultaneously) formed with the emission pattern EP through one process and may be separated from each other by the undercut shape of the anchor portion ACP.

Each of the second-second layer dummy pattern D22 and the second-third layer dummy pattern D23 may include a conductive material. For example, each of the second-second layer dummy pattern D22 and the second-third layer dummy pattern D23 may include the same material as the cathode CE. The second-second layer dummy pattern D22 and the second-third layer dummy pattern D23 may be concurrently (e.g., simultaneously) formed with the cathode CE through one process and may be separated from each other by the undercut shape of the anchor portion ACP.

Each of the third-second layer dummy pattern D32 and the third-third layer dummy pattern D33 may include the same material as the capping pattern CP. The third-second layer dummy pattern D32 and the third-third layer dummy pattern D33 may be concurrently (e.g., simultaneously) formed with the capping pattern CP through one process and may be separated from each other by the undercut shape of the anchor portion ACP.

FIG. 9 illustrates an example that the inner surfaces of the first-third to third-third layer dummy patterns D13, D23, and D33 are aligned with the fourth inner surface S4-P of the second barrier wall layer L2. However, the present disclosure is not limited thereto, and the first-third to third-third layer dummy patterns D13, D23, and D33 may cover the fourth inner surface S4-P of the second barrier wall layer L2.

The display panel DP may further include an outer lower inorganic encapsulation pattern LIL_OT. The outer lower inorganic encapsulation pattern LIL_OT may be disposed in the first non-display area NDAa and the second non-display area NDAb. In the first non-display area NDAa, the outer lower inorganic encapsulation pattern LIL_OT may be disposed on the anchor portion ACP, the second dummy pattern DMP2, and the third dummy pattern DMP3. The outer lower inorganic encapsulation pattern LIL_OT may cover the second dummy pattern DMP2 and the third dummy pattern DMP3 and may be partially disposed in the anchor openings OP-AC. As illustrated in FIG. 8, the outer lower inorganic encapsulation pattern LIL_OT may overlap the plurality of anchor openings OP-AC. The outer lower inorganic encapsulation pattern LIL_OT may make contact with the third inner surface S3-P and the fourth inner surface S4-P of the barrier wall PW in the anchor openings OP-AC. In the anchor openings OP-AC, the outer lower inorganic encapsulation pattern LIL_OT may make contact with the lower surface of the second barrier wall layer L2 exposed from the first barrier wall layer L1.

The outer lower inorganic encapsulation pattern LIL_OT may cover the outer portion OTP in the second non-display area NDAb. The outer lower inorganic encapsulation pattern LIL_OT may be partially disposed in the outer openings OP-OT. In the outer openings OP-OT, the outer lower inorganic encapsulation pattern LIL_OT may make contact with the inner surfaces of the barrier wall PW.

In one or more embodiments, the outer lower inorganic encapsulation pattern LIL_OT may have a one-body shape with a lower inorganic encapsulation pattern LIL adjacent to the first non-display area NDAa from among lower inorganic encapsulation patterns LIL. However, without being limited thereto, the outer lower inorganic encapsulation pattern LIL_OT may be spaced (e.g., spaced apart) from the lower inorganic encapsulation patterns LIL.

According to this embodiment, the anchor may be disposed in the first non-display area NDAa and may be provided in the form of a protruding pattern. Accordingly, the third dummy pattern DMP3 formed in the first non-display area NDAa by the process of forming the emission pattern EP may be disposed on the anchor. In addition, the outer lower inorganic encapsulation pattern LIL_OT may cover the anchor provided in the form of the protruding pattern and thus may be fixed by the anchor. In one or more embodiments, the anchor may have an undercut shape on the section, and thus the outer lower inorganic encapsulation pattern LIL_OT may be more stably fixed. Accordingly, the third dummy pattern DMP3 may also be stably covered by the outer lower inorganic encapsulation pattern LIL_OT, and separation of the third dummy pattern DMP3 may be prevented even though the third dummy pattern DMP3 has a small adhesive force with the anchor.

According to this embodiment, the anchor may be provided from the barrier wall PW. The undercut shape of the anchor may be provided by the anchor opening OP-AC of the barrier wall PW, and the anchor opening OP-AC may be formed through the same process as the process of forming the barrier wall opening OP-P. Accordingly, the anchor according to this embodiment may be provided without an additional process.

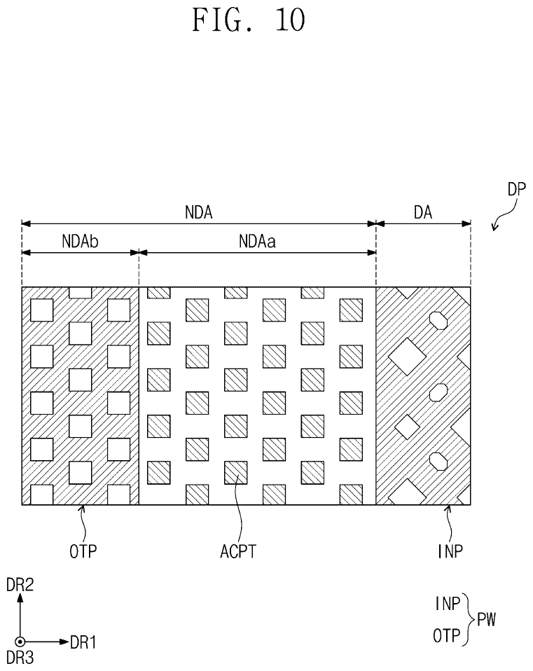

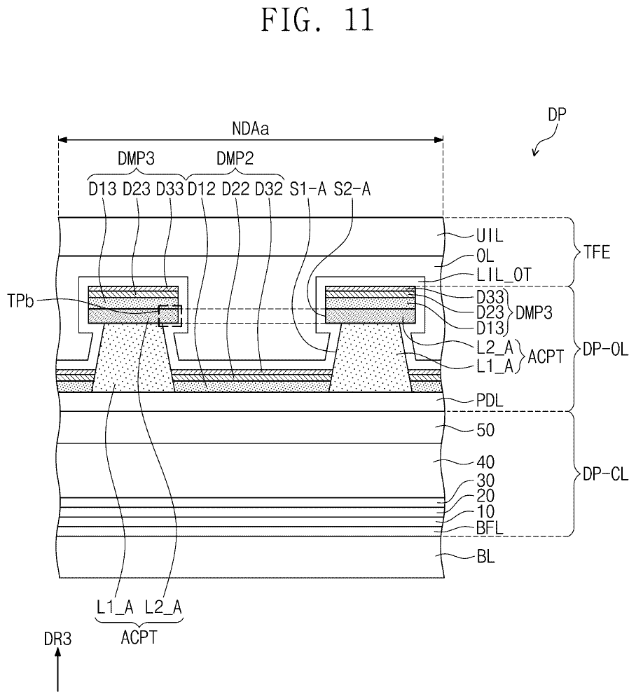

FIG. 10 is an enlarged plan view of a partial region of the display panel according to one or more embodiments of the present disclosure. FIG. 11 is an enlarged sectional view of a portion of the first non-display area of the display panel according to one or more embodiments of the present disclosure.

Referring to FIGS. 10 and 11, the display panel DP according to this embodiment may further include a plurality of anchor patterns ACPT spaced (e.g., spaced apart) from the barrier wall PW. The anchor patterns ACPT may be spaced (e.g., spaced apart) from one another. The anchor may be provided through the plurality of anchor patterns ACPT. For example, as illustrated in FIG. 10, the anchor patterns ACPT may be arranged in a matrix (or, lattice) form. Although FIG. 10 illustrates an example that the anchor patterns ACPT have a square shape when viewed from above the plane, the shape of the anchor patterns ACPT on the plane is not limited to any one embodiment.

As illustrated in FIG. 11, each of the anchor patterns ACPT may have an undercut shape on the section. The anchor pattern ACPT may include multiple layers sequentially stacked one above another, and at least one layer from among the multiple layers may be recessed relative to layers stacked adjacent thereto. Accordingly, the anchor pattern ACPT may include a tip portion TPb.

The anchor pattern ACPT may include a first anchor layer L1_A and a second anchor layer L2_A disposed on the first anchor layer L1_A. In one or more embodiments, in the process of forming the barrier wall openings OP-P (refer to FIG. 5) in a preliminary barrier wall to form the barrier wall PW, the anchor patterns ACPT may be formed by making portions of the preliminary barrier wall subject to patterning. That is, the barrier wall PW and the anchor patterns ACPT may be formed from the preliminary barrier wall through the patterning process of the preliminary barrier wall. The first anchor layer L1_A may include the same material as the first barrier wall layer L1 (refer to FIG. 5) of the barrier wall PW, and the second anchor layer L2_A may include the same material as the second barrier wall layer L2 (refer to FIG. 5) of the barrier wall PW. The etch rates of the first barrier wall layer L1 (refer to FIG. 5) and the first anchor layer L1_A may be greater than the etch rates of the second barrier wall layer L2 (refer to FIG. 5) and the second anchor layer L2_A. Accordingly, the first anchor layer L1_A of each of the anchor patterns ACPT may have a shape recessed relative to the second anchor layer L2_A. That is, the first anchor layer L1_A of each of the anchor patterns ACPT may be undercut with respect to the second anchor layer L2_A.

Each of the anchor patterns ACPT may include a first outer surface S1-A of the first anchor layer L1_A and a second outer surface S2-A of the second anchor layer L2_A, and the first outer surface S1-A may be recessed inward relative to the second outer surface S2-A. Alternatively, the second outer surface S2-A of the second anchor layer L2_A of the anchor pattern ACPT may protrude further than the outer surface S1-A of the first anchor layer L1_A. The first outer surface S1-A may be undercut with respect to the second outer surface S2-A.

The second dummy pattern DMP2 may be disposed on the upper surface of the pixel defining layer PDL exposed from the anchor patterns ACPT. A plurality of third dummy patterns DMP3 may be provided. The plurality of third dummy patterns DMP3 may be disposed on the anchor patterns ACPT, respectively.

The outer lower inorganic encapsulation pattern LIL_OT may be disposed on the anchor patterns ACPT, the second dummy pattern DMP2, and the third dummy pattern DMP3. The outer lower inorganic encapsulation pattern LIL_OT may cover the second dummy pattern DMP2 and the third dummy pattern DMP3. The outer lower inorganic encapsulation pattern LIL_OT may make contact with the first outer surface S1-A and the second outer surface S2-A of each of the anchor patterns ACPT. The outer lower inorganic encapsulation pattern LIL_OT may make contact with the lower surface of the second anchor layer L2_A exposed from the first anchor layer L1_A of the anchor pattern ACPT.

According to this embodiment, the anchor may be disposed in the first non-display area NDAa and may be provided in the form of a protruding pattern. Accordingly, the third dummy patterns DMP3 formed in the first non-display area NDAa by the process of forming the emission pattern EP may be disposed on the anchor. In addition, the outer lower inorganic encapsulation pattern LIL_OT may cover the anchor provided in the form of the protruding pattern and thus may be fixed by the anchor. In one or more embodiments, the anchor may have an undercut shape on the section, and thus the outer lower inorganic encapsulation pattern LIL_OT may be more stably fixed. Accordingly, the third dummy patterns DMP3 may also be stably covered by the outer lower inorganic encapsulation pattern LIL_OT, and separation of the third dummy patterns DMP3 may be prevented even though the third dummy patterns DMP3 have a small adhesive force with the anchor.

In addition, according to this embodiment, the anchor may be provided by the anchor patterns ACPT formed through the same process as that of the barrier wall PW, and the undercut shape of the anchor patterns ACPT may be formed through the same process as the process of forming the barrier wall opening OP-P in the barrier wall PW. Accordingly, the anchor according to this embodiment may be provided without an additional process.

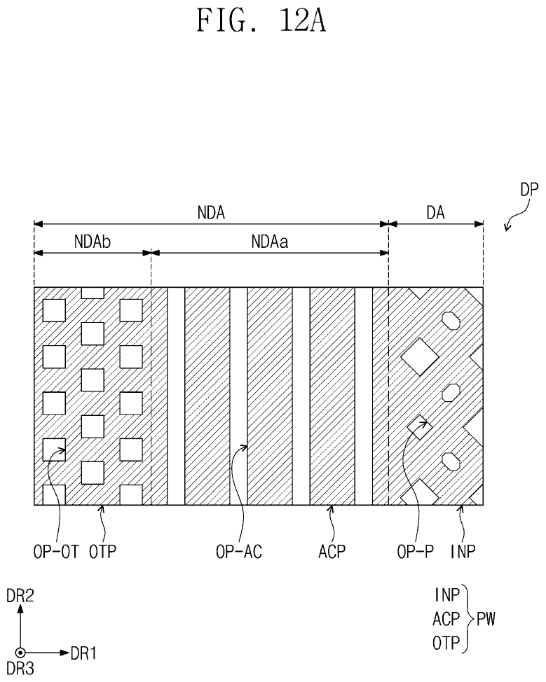

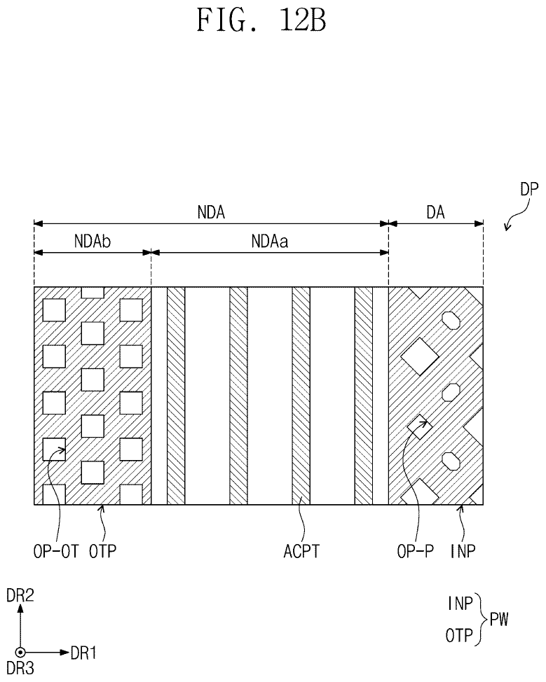

FIGS. 12A and 12B are enlarged plan views of a partial region of the display panel according to one or more embodiments of the present disclosure.

Referring to FIG. 12A, in this embodiment, the barrier wall PW may include the inner portion INP, the anchor portion ACP, and the outer portion OTP, and the anchor may be provided from the anchor portion ACP of the barrier wall PW. The anchor openings OP-AC may be defined in the anchor portion ACP. Each of the anchor openings OP-AC may have a line shape on the plane. For example, the anchor opening OP-AC may extend in the same direction as the direction in which the first non-display area NDAa extends. In other words, the anchor opening OP-AC may extend in the direction perpendicular to the direction toward the second non-display area NDAb from the display area DA.

Referring to FIG. 12B, the display panel DP according to this embodiment may include the anchor patterns ACPT spaced (e.g., spaced apart) from one another, and the anchor may be provided through the anchor patterns ACPT. The anchor patterns ACPT may be components spaced (e.g., spaced apart) from the barrier wall PW (e.g., INP, OTP). Each of the anchor patterns ACPT may have a line shape on the plane. For example, the anchor pattern ACPT may extend in the same direction as the direction in which the first non-display area NDAa extends. In other words, the anchor pattern ACPT may extend in the direction perpendicular to the direction toward the second non-display area NDAb from the display area DA.

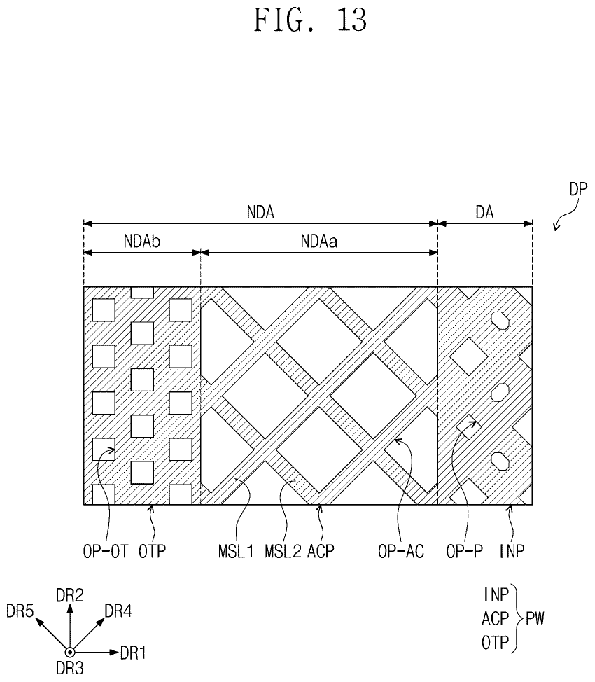

FIG. 13 is an enlarged plan view of a partial region of the display panel according to one or more embodiments of the present disclosure.

Referring to FIG. 13, in this embodiment, the barrier wall PW may include the inner portion INP, the anchor portion ACP, and the outer portion OTP, and the anchor may be provided from the anchor portion ACP of the barrier wall PW. The anchor portion ACP may have a mesh shape on the plane. The mesh shape of the anchor portion ACP may include first mesh lines MSL1 extending in the fourth direction DR4 and second mesh lines MSL2 extending in a fifth direction DR5 (e.g., the fifth direction may be perpendicular to the fourth direction DR4). The fifth direction DR5 may be defined as a direction that crosses the first direction DR1, the second direction DR2, and the forth direction DR4 when viewed from above the plane defined by the first direction DR1 and the second direction DR2. The anchor openings OP-AC may be defined in the anchor portion ACP. Each of the anchor openings OP-AC may have a rhombic shape on the plane.

FIG. 13 illustrates an example that the anchor is provided by the anchor portion ACP of the barrier wall PW. According to one or more embodiments of the present disclosure, the anchor may be provided by the anchor patterns ACPT (refer to FIG. 10) spaced (e.g., spaced apart) from the barrier wall PW, and the anchor patterns ACPT (refer to FIG. 10) may have a mesh shape.

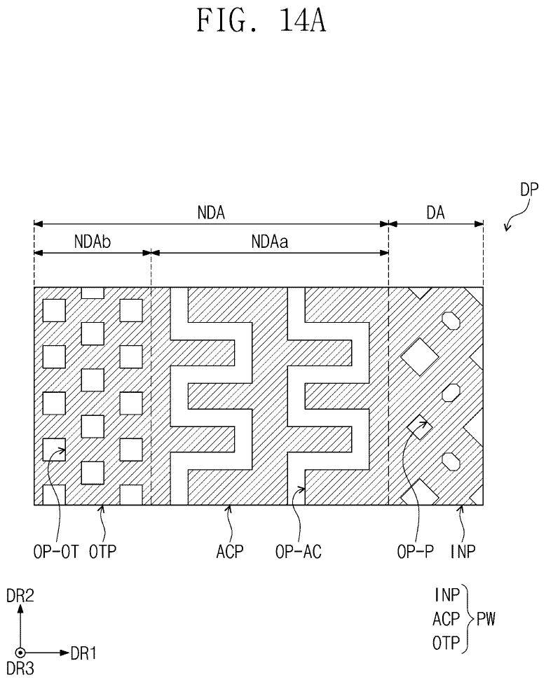

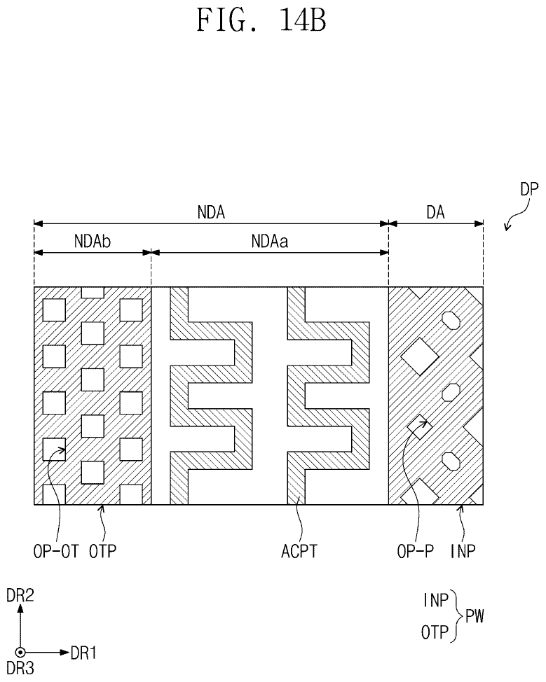

FIGS. 14A and 14B are enlarged plan views of a partial region of the display panel according to one or more embodiments of the present disclosure.

Referring to FIG. 14A, in this embodiment, the barrier wall PW may include the inner portion INP, the anchor portion ACP, and the outer portion OTP, and the anchor may be provided from the anchor portion ACP of the barrier wall PW. The anchor openings OP-AC may be defined in the anchor portion ACP. Each of the anchor openings OP-AC may have a zigzag shape on the plane. For example, the zigzag shape of the anchor opening OP-AC may include portions extending in the first direction DR1 and portions extending in the second direction DR2. However, the extension directions of the portions in the zigzag shape are not limited to any one embodiment.

Referring to FIG. 14B, the display panel DP according to this embodiment may include the anchor patterns ACPT spaced (e.g., spaced apart) from one another, and the anchor may be provided through the anchor patterns ACPT. The anchor patterns ACPT may be components that are spaced (e.g., spaced apart) from the barrier wall PW. Each of the anchor patterns ACPT may have a zigzag shape on the plane. For example, the zigzag shape of the anchor pattern ACPT may include portions extending in the first direction DR1 and portions extending in the second direction DR2. However, the extension directions of the portions in the zigzag shape are not limited to any one embodiment.

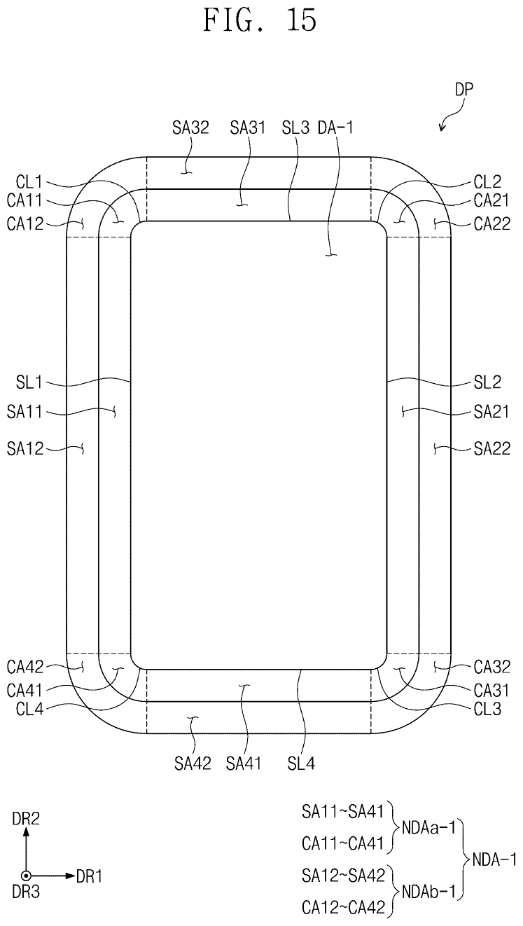

FIG. 15 is a schematic plan view of the display panel according to one or more embodiments of the present disclosure.

Referring to FIG. 15, a display area DA-1 according to this embodiment may have a quadrangular shape when viewed from above the plane. The display area DA-1 may have a shape in which four corners at each of which two sides meet are all rounded (or, have a certain curvature). Accordingly, the display area DA-1 may include first to fourth straight sides SL1, SL2, SL3, and SL4 and first to fourth curved sides CL1, CL2, CL3, and CL4 on the plane. The first and second straight sides SL1 and SL2 may be spaced (e.g., spaced apart) from each other in the first direction DR1 and may extend in the second direction DR2. The third and fourth straight sides SL3 and SL4 may be spaced (e.g., spaced apart) from each other in the second direction DR2 and may extend in the first direction DR1. The first curved side CL1 may be disposed between the first and third straight sides SL1 and SL3, and the second curved side CL2 may be disposed between the second and third straight sides SL2 and SL3. The third curved side CL3 may be disposed between the second and fourth straight sides SL2 and SL4, and the fourth curved side CL4 may be disposed between the first and fourth straight sides SL1 and SL4.

A non-display area NDA-1 according to this embodiment may extend along the outer sides of the display area DA-1. A first non-display area NDAa-1 may include first-first to fourth-first straight areas SA11, SA21, SA31, and SA41 and first-first to fourth-first curved areas CA11, CA21, CA31, and CA41. The first-first and second-first straight areas SA11 and SA21 may extend along the first and second straight sides SL1 and SL2 of the display area DA-1, respectively, and may extend in the second direction DR2. The third-first and fourth-first straight areas SA31 and SA41 may extend along the third and fourth straight sides SL3 and SL4 of the display area DA-1, respectively, and may extend in the first direction DR1. The first-first to fourth-first curved areas CA11, CA21, CA31, and CA41 may extend along the first to fourth curved sides CL1, CL2, CL3, and CL4 of the display area DA-1, respectively.

A second non-display area NDAb-1 may include first-second to fourth-second straight areas SA12, SA22, SA32, and SA42 and first-second to fourth-second curved areas CA12, CA22, CA32, and CA42. The first-second and second-second straight areas SA12 and SA22 may extend along the first-first and second-first straight areas SA11 and SA21 of the first non-display area NDAa-1 and may extend in the second direction DR2. The third-second and fourth-second straight areas SA32 and SA42 may extend along the third-first and fourth-first straight areas SA31 and SA41 of the first non-display area NDAa-1 and may extend in the first direction DR1. The first-second to fourth-second curved areas CA12, CA22, CA32, and CA42 may extend along the first-first to fourth-first curved areas CA11, CA21, CA31, and CA41 of the first non-display area NDAa-1, respectively.

In this embodiment, the anchor may be disposed in the first non-display area NDAa-1. For example, the anchor may be disposed not only in the first-first to fourth-first straight areas SA11 to SA41 but also in the first-first to fourth-first curved areas CA11 to CA41. That is, the anchor may be disposed in at least a part of the first-first to fourth-first curved areas CA11 to CA41.

In one or more embodiments, the shape of the display area DA-1 is not limited thereto. The display area DA-1 may have a shape in which only some of the corners at each of which two sides meet have a rounded shape and the other corners have a right-angled shape. In this case, some of the curved areas may be omitted.

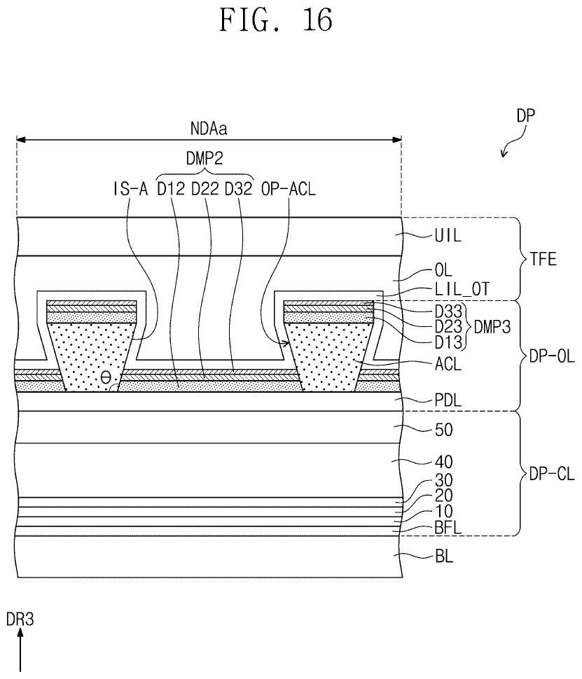

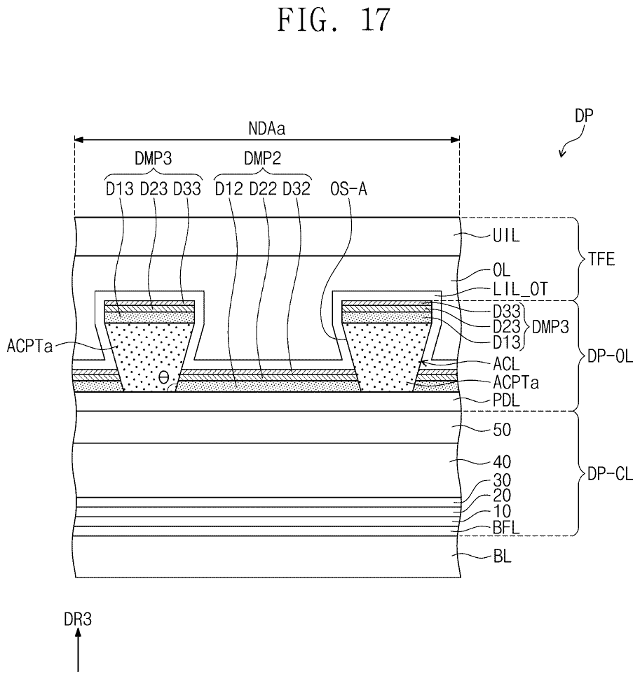

FIGS. 16 and 17 are enlarged sectional views of a portion of the first non-display area of the display panel according to one or more embodiments of the present disclosure.

Referring to FIGS. 16 and 17, the display panel DP according to this embodiment may further include an anchor layer ACL. The anchor layer ACL may be disposed in the first non-display area NDAa. The anchor layer ACL may be disposed on the pixel defining layer PDL. In this embodiment, the anchor may be provided from the anchor layer ACL.

The anchor layer ACL may have an inverted tapered shape on the section. That is, the angle θ (hereinafter, referred to as the taper angle) formed by the side surface of the anchor layer ACL with respect to the upper surface of the pixel defining layer PDL (or, the lower surface of the anchor layer ACL that makes contact with the upper surface of the pixel defining layer) may be an obtuse angle. The width of the anchor layer ACL on the section may be increased farther away from the upper surface of the pixel defining layer PDL.

In one or more embodiments, the anchor layer ACL may include an organic material. However, the present disclosure is not limited thereto, and the anchor layer ACL may include an inorganic material, or may have a multi-layer structure including an organic film and/or an inorganic film. In one or more embodiments, the anchor layer ACL may include a conductive material. No special limitation applies to the type of the material of the anchor layer ACL, as long as the anchor layer ACL is able to be formed to have an inverted tapered shape on the section.

The second dummy pattern DMP2 and the third dummy pattern DMP3 may be formed together with the emission pattern EP in the process of forming the emission pattern EP and may be separated from each other by the inverted tapered shape of the anchor layer ACL.

Referring to FIG. 16, the anchor layer ACL according to one or more embodiments may have anchor openings OP-ACL defined therein. Each of the inner surfaces IS-A of the anchor layer ACL that define the anchor openings OP-ACL may have an obtuse taper angle θ. On the section, each of the anchor openings OP-ACL may have a decreasing width farther away from the upper surface of the pixel defining layer PDL. A plurality of second dummy patterns DMP2 may be provided. The plurality of second dummy patterns DMP2 may be spaced (e.g., spaced apart) from one another. The second dummy patterns DMP2 may be disposed in the anchor openings OP-ACL, respectively. The second dummy patterns DMP2 may be directly disposed on the pixel defining layer PDL. The third dummy pattern DMP3 may be disposed on the upper surface of the anchor layer ACL.

The outer lower inorganic encapsulation pattern LIL_OT may be disposed on the anchor layer ACL, the second dummy patterns DMP2, and the third dummy pattern DMP3. The outer lower inorganic encapsulation pattern LIL_OT may cover the second dummy patterns DMP2 and the third dummy pattern DMP3 and may be partially disposed in the anchor openings OP-ACL. In the anchor openings OP-ACL, the outer lower inorganic encapsulation pattern LIL_OT may make contact with the inner surfaces IS-A of the anchor layer ACL.

Referring to FIG. 17, the anchor layer ACL according to one or more embodiments may include a plurality of anchor patterns ACPTa. The anchor patterns ACPTa may be spaced (e.g., spaced apart) from one another. Each of the anchor patterns ACPTa may have an inverted tapered shape on the section. Each of the outer surfaces OS-A of the anchor patterns ACPTa may have an obtuse taper angle θ. The second dummy pattern DMP2 may be disposed on the upper surface of the pixel defining layer PDL exposed from the anchor patterns ACPTa. A plurality of third dummy patterns DMP3 may be provided. The plurality of third dummy patterns DMP3 may be disposed on the anchor patterns ACPTa, respectively.

The outer lower inorganic encapsulation pattern LIL_OT may be disposed on the anchor patterns ACPTa, the second dummy pattern DMP2, and the third dummy patterns DMP3. The outer lower inorganic encapsulation pattern LIL_OT may cover the second dummy pattern DMP2 and the third dummy patterns DMP3. The outer lower inorganic encapsulation pattern LIL_OT may make contact with the outer surfaces OS-A of the anchor patterns ACPTa.

According to this embodiment, the anchor may be disposed in the first non-display area NDAa and may be provided in the form of a protruding pattern. Accordingly, the third dummy pattern DMP3 formed in the first non-display area NDAa by the process of forming the emission pattern EP may be disposed on the anchor. In addition, the outer lower inorganic encapsulation pattern LIL_OT may cover the anchor provided in the form of the protruding pattern and thus may be fixed by the anchor. In one or more embodiments, the anchor may have an inverted tapered shape on the section, and thus the outer lower inorganic encapsulation pattern LIL_OT may be more stably fixed. Accordingly, the third dummy pattern DMP3 may also be stably covered by the outer lower inorganic encapsulation pattern LIL_OT, and separation of the third dummy pattern DMP3 may be prevented even though the third dummy pattern DMP3 has a small adhesive force with the anchor.

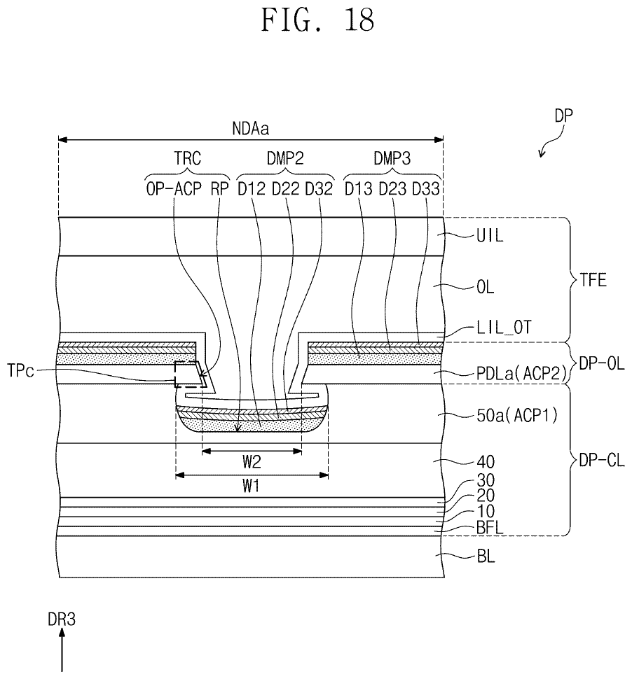

FIG. 18 is an enlarged sectional view of a portion of the first non-display area of the display panel according to one or more embodiments of the present disclosure.

Referring to FIG. 18, the display panel DP according to this embodiment may include a trench TRC in the first non-display area NDAa.

In the first non-display area NDAa, an anchor opening OP-ACP may be defined in a pixel defining layer PDLa. In the first non-display area NDAa, a recessed portion RP may be defined in an insulating layer disposed under the pixel defining layer PDLa, for example, in a fifth insulating layer 50a. The anchor opening OP-ACP may overlap the recessed portion RP. That is, the anchor opening OP-ACP and the recessed portion RP may form an integrated space. The trench TRC may be provided by the recessed portion RP of the fifth insulating layer 50a and the anchor opening OP-ACP of the pixel defining layer PDLa that form the integrated space.

The anchor according to this embodiment may include a first anchor portion ACP1 and a second anchor portion ACP2. In this embodiment, the portion of the fifth insulating layer 50a disposed in the first non-display area NDAa is defined as the first anchor portion ACP1, and the portion of the pixel defining layer PDLa disposed in the first non-display area NDAa is defined as the second anchor portion ACP2. According to this embodiment, the anchor may be provided by the fifth insulating layer 50a and the pixel defining layer PDLa. That is, the anchor may have a trench shape provided by the fifth insulating layer 50a and the pixel defining layer PDLa.

The maximum width W1 of the recessed portion RP on the section may be greater than the width W2 of the anchor opening OP-ACP on the section. The portion of the pixel defining layer PDLa that overlaps the recessed portion RP may have a shape protruding from the fifth insulating layer 50a toward the inside of the trench TRC. The lower surface of the pixel defining layer PDLa that overlaps the recessed portion RP may be exposed without being covered by the fifth insulating layer 50a. The portion of the pixel defining layer PDLa that protrudes from the fifth insulating layer 50a toward the inside of the trench TRC may define a tip portion TPc.

Although FIG. 18 illustrates an example that the width W2 of the anchor opening OP-ACP is decreased toward the recessed portion RP in the thickness direction (e.g., in the third direction DR3), the present disclosure is not limited thereto.

The second dummy pattern DMP2 and the third dummy pattern DMP3 may be formed together with the emission pattern EP in the process of forming the emission pattern EP and may be separated from each other by the tip portion TPc of the pixel defining layer PDLa. The second dummy pattern DMP2 may be disposed in the recessed portion RP. The third dummy pattern DMP3 may be disposed on the upper surface of the pixel defining layer PDLa in the first non-display area NDAa.

The outer lower inorganic encapsulation pattern LIL_OT may be disposed on the first anchor portion ACP1, the second anchor portion ACP2, the second dummy pattern DMP2, and the third dummy pattern DMP3. The outer lower inorganic encapsulation pattern LIL_OT may cover the second dummy pattern DMP2 and the third dummy pattern DMP3 and may be partially disposed in the trench TRC. In the trench TRC, the outer lower inorganic encapsulation pattern LIL_OT may make contact with the fifth insulating layer 50a and the pixel defining layer PDLa. The outer lower inorganic encapsulation pattern LIL_OT may make contact with the inner surface of the pixel defining layer PDLa that defines the anchor opening OP-ACP and the lower surface of the pixel defining layer PDLa exposed from the fifth insulating layer 50a.

According to this embodiment, the anchor may be disposed in the first non-display area NDAa and may be provided in the form of a protruding pattern. Accordingly, the third dummy pattern DMP3 formed in the first non-display area NDAa by the process of forming the emission pattern EP may be disposed on the anchor. In addition, the outer lower inorganic encapsulation pattern LIL_OT may cover the anchor provided in the form of the protruding pattern and thus may be fixed by the anchor. In one or more embodiments, the anchor may have a trench shape on the section, and thus the outer lower inorganic encapsulation pattern LIL_OT may be more stably fixed. Accordingly, the third dummy pattern DMP3 may also be stably covered by the outer lower inorganic encapsulation pattern LIL_OT, and separation of the third dummy pattern DMP3 may be prevented even though the third dummy pattern DMP3 has a small adhesive force with the anchor.

According to the present disclosure, the anchor may be provided in the non-display area, and the inorganic encapsulation pattern (or, the outer lower inorganic encapsulation pattern) disposed in the non-display area may be fixed by the anchor. Accordingly, the dummy patterns deposited on the non-display area in the process of forming the emission pattern may be prevented from being separated from the anchor. Thus, the display panel with improved process reliability may be provided.

While the present disclosure has been described with reference to embodiments thereof, it will be apparent to those of ordinary skill in the art that various changes and modifications may be made thereto without departing from the spirit and scope of the present disclosure as set forth in the following claims and their equivalents.

What is claimed is:

1. A display panel comprising:
a base layer;
a pixel defining layer on the base layer, the pixel defining layer having a light emitting opening in a display area;
a barrier wall on the pixel defining layer, the barrier wall having a barrier wall opening in the display area and overlapping the light emitting opening;
an anode in the display area and at least partially exposed by the light emitting opening;
a cathode in the display area and contacting with the barrier wall in the barrier wall opening;
an emission pattern located between the anode and the cathode; and
an anchor in a non-display area surrounding at least a portion of the display area.

2. The display panel of claim 1, wherein the barrier wall comprises:
a first barrier wall layer on the pixel defining layer; and
a second barrier wall layer on the first barrier wall layer, and
wherein the barrier wall opening includes:
a first opening area defined by an inner surface of the first barrier wall layer; and
a second opening area defined by an inner surface of the second barrier wall layer, the second opening area having a smaller width than the first opening area.

3. The display panel of claim 1, further comprising:
a first dummy pattern on the barrier wall, the first dummy pattern including a first-first layer dummy pattern comprising a same material as the emission pattern and a second-first layer dummy pattern including a same material as the cathode; and
a lower inorganic encapsulation pattern at least partially overlapping the barrier wall opening and covering the cathode.

4. The display panel of claim 2, wherein the non-display area includes a first non-display area and a second non-display area spaced from the display area with the first non-display area therebetween, and
wherein the barrier wall comprises:
an inner portion in the display area, the inner portion having the barrier wall opening; and
an outer portion in the second non-display area, the outer portion having an outer opening.

5. The display panel of claim 4, further comprising:
a driving voltage line at least partially located in the second non-display area and configured to receive a bias voltage,
wherein the outer portion of the barrier wall is connected to the driving voltage line in the second non-display area.

6. The display panel of claim 4, wherein the barrier wall further comprises an anchor portion in the first non-display area, the anchor portion having an anchor opening, and
wherein the anchor is provided by the anchor portion of the barrier wall.

7. The display panel of claim 6, wherein the anchor opening includes:
a third opening area defined by an inner surface of the first barrier wall layer; and
a fourth opening area defined by an inner surface of the second barrier wall layer, the fourth opening area having a smaller width than the third opening area.

8. The display panel of claim 6, further comprising:
a second dummy pattern in the anchor opening, the second dummy pattern including a first-second layer dummy pattern including a same material as the emission pattern and a second-second layer dummy pattern including a same material as the cathode; and
a third dummy pattern on the anchor portion of the anchor, the third dummy pattern comprising a first-third layer dummy pattern including a same material as the emission pattern and a second-third layer dummy pattern including a same material as the cathode.

9. The display panel of claim 8, further comprising:
an outer lower inorganic encapsulation pattern in the non-display area and covering the second dummy pattern and the third dummy pattern.

10. The display panel of claim 6, wherein the anchor opening includes a plurality of anchor openings, and the plurality of anchor openings are arranged in a matrix form on a plane.

11. The display panel of claim 6, wherein the anchor opening has one of a line shape, a mesh shape, or a zigzag shape on a plane.

12. The display panel of claim 4, further comprising:
anchor patterns in the first non-display area and spaced from the barrier wall,
wherein each of the anchor patterns comprises:
a first anchor layer on the pixel defining layer, the first anchor layer comprising a same material as the first barrier wall layer; and
a second anchor layer on the first anchor layer, the second anchor layer comprising a same material as the second barrier wall layer,
wherein an outer surface of the second anchor layer protrudes further than an outer surface of the first anchor layer, and
wherein the anchor is provided by the anchor patterns.

13. The display panel of claim 12, further comprising:
a second dummy pattern on an upper surface of the pixel defining layer exposed from the anchor patterns, the second dummy pattern including a first-second layer dummy pattern including a same material as the emission pattern and a second-second layer dummy pattern including a same material as the cathode;
third dummy patterns on the anchor patterns, respectively, the third dummy patterns including a first-third layer dummy pattern including a same material as the emission pattern and a second-third layer dummy pattern including a same material as the cathode; and
an outer lower inorganic encapsulation pattern in the first non-display area and covering the second dummy patterns and the third dummy patterns.

14. The display panel of claim 12, wherein the anchor patterns are arranged in a matrix form on a plane, or each of the anchor patterns has one of a line shape, a mesh shape, or a zigzag shape on a plane.

15. The display panel of claim 4, further comprising:
an anchor layer in the first non-display area and spaced from the barrier wall, the anchor layer having an inverted tapered shape on a section,
wherein the anchor is provided by the anchor layer.

16. The display panel of claim 4, further comprising:
an insulating layer under the pixel defining layer, the insulating layer having a recessed portion in the first non-display area,
wherein the pixel defining layer has an anchor opening overlapping the recessed portion and forming an integrated space with the recessed portion, and the recessed portion and the anchor opening provide a trench, and
wherein the anchor is provided by the insulating layer located in the first non-display area and the pixel defining layer in the first non-display area.

17. The display panel of claim 16, wherein a maximum width of the recessed portion on a section is greater than a width of the anchor opening on the section, and a portion of the pixel defining layer protruding toward the inside of the trench from the insulating layer defines a tip portion.

18. The display panel of claim 1, wherein the display area includes:
a first straight side and a second straight side spaced from each other in a first direction and configured to extend along a second direction crossing the first direction;
a third straight side and a fourth straight side spaced from each other in the second direction and configured to extend along the first direction; and
first to fourth curved sides between the first and third straight sides, between the second and third straight sides, between the third and fourth straight sides, and between the first and fourth straight sides, respectively,
wherein a first non-display area includes:
first-first and second-first straight areas extending along the first and second straight sides, respectively;
third-first and fourth-first straight areas extending along the third and fourth straight sides, respectively; and
first-first to fourth-first curved areas extending along the first-first to fourth-first curved sides, respectively, and
wherein the anchor is in at least a part of the first-first to fourth-first curved areas.

19. A display panel comprising:
a base layer;
a pixel defining layer on the base layer, the pixel defining layer having a light emitting opening in a display area;
a barrier wall on the pixel defining layer, the barrier wall having a barrier wall opening in the display area and overlapping the light emitting opening;
an anode in the display area and at least partially exposed by the light emitting opening;
a cathode in the display area and configured to make contact with the barrier wall in the barrier wall opening;
an emission pattern between the anode and the cathode;
an anchor in a first non-display area surrounding at least a portion of the display area;
a first dummy pattern on the barrier wall in the display area;
a second dummy pattern on an upper surface of the pixel defining layer exposed from the anchor in the first non-display area;
a third dummy pattern on the anchor in the first non-display area; and
an outer lower inorganic encapsulation pattern covering the anchor, the second dummy pattern, and the third dummy pattern,
wherein the barrier wall comprises an inner portion in the display area and an outer portion in a second non-display area spaced from the display area with the first non-display area therebetween.

20. The display panel of claim 19, wherein the anchor has one of an undercut shape, an inverted tapered shape, or a trench shape on a section.

21. An electronic device comprising:
a processor configured to provide input image data to a display panel, the display panel comprising:
a base layer;
a pixel defining layer on the base layer, the pixel defining layer having a light emitting opening in a display area;
a barrier wall on the pixel defining layer, the barrier wall having a barrier wall opening in the display area and overlapping the light emitting opening;
an anode in the display area and at least partially exposed by the light emitting opening;
a cathode in the display area and contacting with the barrier wall in the barrier wall opening;
an emission pattern located between the anode and the cathode;
an anchor in a non-display area surrounding at least a portion of the display area; and
a first dummy pattern on the barrier wall.

22. The electronic device of claim 21, wherein the electronic device is a personal computer, a notebook computer, a personal digital terminal, a car navigation unit, a game machine, a smart phone, a tablet computer, or a camera.
